(19) United States
(12) Patent Application Publication
(10) Pub. No.: US 2026/0363137 A1
(43) Pub. Date: Nov. 12, 2026

(54) Semiconductor Device and Manufacturing Method Thereof

(71) Applicant: Diodes Incorporated, Plano, TX (US)

(72) Inventors: Kuo-Liang CHAO, Hsinchu (TW); Pin-Hao HUANG, New Taipei City (TW); Bau-Shun HUANG, New Taipei City (TW); Chih-Hung TSAI, Keelung City (TW)

(21) Appl. No.: 19/399,984

(22) Filed: Nov. 25, 2025

(30) Foreign Application Priority Data
May 8, 2025 (CN) 202510586534.5

(51) Int. Cl. H10W 74/10; H10D 80/20; H10P 54/00; H10W 20/40; H10W 74/01; H10W 90/00; H10W 74/47

(52) U.S. Cl. CPC H10W 74/147; H10D 80/231; H10P 54/00; H10W 20/40; H10W 74/01; H10W 74/137; H10W 90/00; H10W 74/47

(57) ABSTRACT

A semiconductor device includes semiconductor dies, each of which includes: a portion of a substrate and epitaxial layer, a rectifier structure on a top surface of the substrate and epitaxial layer, a first electrode on the rectifier structure, and a second electrode extending from a bottom surface of the substrate and epitaxial layer toward and above the top surface. An isolation structure of polyimide is provided to isolate the semiconductor dies. The isolation structure extends from the top surface toward the bottom surface, and extends through the substrate and epitaxial layer and protrudes from the bottom surface of the substrate and epitaxial layer. A portion of the isolation structure protruding from the bottom surface has a greater width than a portion of the isolation structure in the substrate and epitaxial layer. A method of manufacturing the semiconductor device is also provided.

### CROSS-REFERENCE TO RELATED APPLICATIONS

This patent application claims priority to China Patent Application No. 202510586534.5, filed on May 8, 2025 and entitled “SEMICONDUCTOR DEVICE AND MANUFACTURING METHOD THEREOF,” which is hereby incorporated by reference herein as if reproduced in its entirety.

### TECHNICAL FIELD

The present disclosure relates generally to the field of semiconductors, and in particular embodiments, to techniques and mechanisms for a semiconductor device and a manufacturing method thereof. In some embodiments, a semiconductor device with an isolation structure and a manufacturing method thereof are provided, where the semiconductor device includes a plurality of semiconductor dies integrated within the semiconductor device.

### BACKGROUND

As well known, semiconductor materials have wide band gaps (e.g., band gap energy values (Eg) greater than 1.1 eV), low on-resistance (RON), high thermal conductivity, high operating frequencies, and high charge carrier saturation velocities, and are well-suited for production of electronic components, such as diodes and transistors, and particularly for power supply applications. A material that possesses these characteristics and is designed for use in manufacture of electronic components is silicon carbide (SiC). In particular, silicon carbide, in its different polytypes (e.g., 3C-SiC, 4H-SiC, 6H-SiC), outperforms silicon with respect to the characteristics listed above.

Electronic devices on silicon carbide substrates offer numerous advantages over similar devices on silicon substrates, including low on-state output resistance, low leakage current, high operating temperature, high operating frequencies, and so on, and are suitable in applications of high-voltage power devices. While these advantages of the silicon carbide substrates over the silicon substrates allow them to withstand higher operating voltages, existing processes for electrical isolation structures fail to achieve the required electrical isolation effect, limiting the application of the silicon carbide substrates.

### SUMMARY

Technical advantages are generally achieved, by embodiments of this disclosure which describe a semiconductor device and a manufacturing method thereof.

Embodiments of the present disclosure relate to a semiconductor device, comprising: a plurality of semiconductor dies, each of the plurality of semiconductor dies comprising a substrate and epitaxial layer, a rectifier structure disposed on a top surface of the substrate and epitaxial layer, a first electrode disposed on the rectifier structure, and a second electrode extending from above a top surface toward a bottom surface of the substrate and epitaxial layer; and an isolation structure for isolating the substrate and epitaxial layer of adjacent semiconductor dies, a material of the isolation structure comprising polyimide, wherein the isolation structure extends from the top surface of the substrate and epitaxial layer toward the bottom surface and protrudes from the bottom surface.

Embodiments of the present disclosure relate to a semiconductor device, comprising: a substrate having a first surface and a second surface opposite to each other; an isolation structure extending from the first surface toward the second surface of the substrate and passing through the substrate, wherein the isolation structure protrudes from the second surface, and the isolation structure at least divides the substrate into a first region and a second region adjacent to each other in a horizontal direction; a first rectifier structure located on the first surface of the first region of the substrate; a second rectifier structure located on the first surface of the second region of the substrate; a first metal layer located on the second surface of the substrate; and a second metal layer located on the first surface of the substrate, the second metal layer comprising: a first electrode pad located on the first rectifier structure and electrically connected to the first rectifier structure; and a second electrode pad having a first portion extending on the first surface of the substrate and a second portion extending from the first surface toward the second surface, wherein the first portion covers a portion of the first region and a portion of the second region and is electrically connected to the second rectifier structure, and the second portion passes through the substrate and is electrically connected to the first metal layer.

Embodiments of the present disclosure relate to a method of manufacturing a semiconductor device. The method includes: forming a first rectifier structure and a second rectifier structure on a first surface of a substrate, wherein the substrate is defined with a first region and a second region adjacent to the first region, and the first rectifier structure and the second rectifier structure are respectively located in the first region and the second region of the substrate; forming a first dielectric layer to cover the substrate, the first rectifier structure and the second rectifier structure, wherein the first dielectric layer has a plurality of openings, respectively exposing a portion of the first rectifier structure, a portion of the second rectifier structure, and a portion of the substrate located between the first rectifier structure and the second rectifier structure; removing the portion of the substrate exposed by the first dielectric layer to form a first opening; forming a first metal layer on the first surface of the substrate and in the first opening; forming a second metal layer on a second surface of the substrate opposite to the first surface, wherein the second metal layer has a second opening exposing the substrate between the first region the second region; removing a portion of the substrate exposed by the second opening of the second metal layer to form a third opening in the substrate; and forming an isolation structure in the third opening and the second opening, wherein the isolation structure protrudes from the second metal layer.

According to one aspect of the present disclosure, a semiconductor device is provided that includes: a plurality of semiconductor dies, each of the plurality of semiconductor dies comprising: a portion of a substrate and epitaxial layer, a rectifier structure disposed on a top surface of the substrate and epitaxial layer, a first electrode disposed on the rectifier structure, and a second electrode extending from a bottom surface of the substrate and epitaxial layer toward and above the top surface of the substrate and epitaxial layer; and an isolation structure of the substrate and epitaxial layer, configured to isolate the plurality of semiconductor dies, wherein the isolation structure comprises polyimide, and extends from the top surface of the substrate and epitaxial layer toward the bottom surface of the substrate and epitaxial layer and protrudes from the bottom surface of the substrate and epitaxial layer.

According to another aspect of the present disclosure, a semiconductor device is provided that includes: a substrate having a first surface and a second surface opposite to each other; an isolation structure extending from the first surface of the substrate toward the second surface of the substrate and protruding from the second surface of the substrate, the isolation structure dividing the substrate at least into a first region and a second region adjacent to each other; a first rectifier structure on the first surface of the substrate in the first region; a second rectifier structure on the first surface of the substrate in the second region; a first metal layer on the second surface of the substrate; and a second metal layer comprising: a first electrode pad on the first rectifier structure and electrically connected to the first rectifier structure; and a second electrode pad, comprising a first portion extending on the first surface of the substrate and a second portion extending from the first surface of the substrate toward the second surface of the substrate, wherein the first portion covers a portion of the first region and a portion of the second region and is electrically connected to the second rectifier structure, and the second portion extends through the substrate and is electrically connected to the first metal layer.

According to yet another aspect of the present disclosure, a method of manufacturing a semiconductor device is provided that includes: forming a first rectifier structure and a second rectifier structure on a first surface of a substrate, wherein the first rectifier structure and the second rectifier structure are respectively located in a first region and a second region of the substrate, the first region being adjacent to the second region; forming a first dielectric layer covering the substrate, the first rectifier structure and the second rectifier structure, wherein the first dielectric layer has a plurality of openings, respectively exposing a portion of the first rectifier structure, a portion of the second rectifier structure, and a first portion of the substrate between the first rectifier structure and the second rectifier structure; forming a first opening extending into the substrate from the first surface of the first portion of the substrate exposed by the first dielectric layer; forming a first metal layer over the first surface of the substrate and in the first opening; forming a second metal layer on a second surface of the substrate opposite to the first surface of the substrate, wherein the second metal layer has a second opening exposing a second portion of the substrate between the first region the second region; forming a third opening extending from the second surface of the second portion of the substrate exposed by the second opening of the second metal layer and extending through the substrate; and forming an isolation structure in the third opening and the second opening, wherein the isolation structure protrudes from the second metal layer away from the substrate.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

In order to make the above features and advantages of the present disclosure more obvious and easier to understand, various embodiments are described in detail below with reference to the accompanying drawings.

### BRIEF DESCRIPTION OF THE DRAWINGS

Aspects of embodiments of the present disclosure may be better understood from the following detailed description when read with the accompanying drawings. It should be noted that various structures may not be drawn to scale. In fact, the dimensions of the various structures may be arbitrarily enlarged or reduced for clarity of discussion.

FIG. 1 is a cross-sectional view of a semiconductor device according to some embodiments of the present application;

FIG. 2 is a top view of the semiconductor device according to some embodiments of the present application;

FIG. 3 is a circuit layout diagram of the semiconductor device according to some embodiments of the present application;

FIGS. 4-19 are cross-sectional views of a semiconductor device in one or more stages of a manufacturing method of the semiconductor device according to some embodiments of the present application; and

FIG. 20 is a flowchart of a method of manufacturing a semiconductor device according to embodiments of the present application.

The same or similar components are denoted by the same reference numerals in the drawings and detailed description. Several embodiments of the present disclosure will be readily understood from the following detailed description taken in conjunction with the accompanying drawings.

### DETAILED DESCRIPTION OF ILLUSTRATIVE EMBODIMENTS

The making and using of embodiments of this disclosure are discussed in detail below. It should be appreciated, however, that the concepts disclosed herein can be embodied in a wide variety of specific contexts, and that the specific embodiments discussed herein are merely illustrative and do not serve to limit the scope of the claims. Further, it should be understood that various changes, substitutions and alterations can be made herein without departing from the spirit and scope of this disclosure as defined by the appended claims.

Furthermore, one or more features from one or more of the following described embodiments may be combined to create alternative embodiments not explicitly described, and features suitable for such combinations are understood to be within the scope of this disclosure. It is therefore intended that the appended claims encompass any such modifications or embodiments.

The following disclosure provides various different embodiments or examples for implementing different features of the presented subject matter. Specific embodiments of components and configurations are described below. Certainly, these are examples only and are not intended to be limiting. In this disclosure, references to forming a first feature over or on a second feature may include embodiments where the first and second features are formed in direct contact, and may also include embodiments where an additional feature is formed between the first feature and the second feature such that the first feature and the second feature may not be in direct contact. In addition, the present disclosure may repeat reference signs and/or letters in various embodiments. Such repetition is for simplicity and clarity and does not in itself indicate relationships between the various embodiments and/or configurations discussed.

Embodiments of the present disclosure are discussed in detail below. It should be appreciated, however, that the present disclosure provides applicable concepts that can be embodied in a wide variety of specific contexts. The specific embodiments discussed herein are illustrative only, and do not limit the scope of the present disclosure.

The embodiments are described in detail with reference to the accompanying drawings, but the embodiments are not intended to limit the scope of the present disclosure. In addition, each figure is only for illustration purposes and may not be drawn based on the original dimension, and therefore the size and ratio may be inconsistent with the actual dimension.

The terms "top," "bottom," and "side" are used with reference to the accompanying drawings and should not be construed as indications of orientation limitations in description of physical devices.

The term "photolithography" refers to a microfabrication process for patterning parts on a thin film or the bulk of a wafer, in which a series of processes are performed in sequence including applying photoresist, exposing, developing, and curing.

The term "front-end processing" refers to processing steps of a semiconductor die, which typically begins with fabrication of circuit elements embedded in and on the die and ends with formation of a passivation layer. The term "front-end etching process" refers to an etching process performed during the front-end processing, which is typically used to form patterns on the surface of the die. A typical “front-end etching process” may include, for example, wet chemical etching.

The term "back-end processing" refers to processing steps of a semiconductor die, which typically begins when the front-end processing is completed and typically includes back grinding, die bonding, wire bonding, molding, sawing, and testing. The term " back-end etching process" refers to an etching process performed during the back-end processing, which may be used to form a pattern on the bottom of the die. A typical "back-end etching process" may include, for example, plasma etching or sawing.

Embodiments of the present disclosure provide a semiconductor device structure including a rectifier device and a manufacturing method thereof. Compared to conventional semiconductor devices, the semiconductor device of embodiments of the present disclosure comprises a substrate and an epitaxial layer, and an isolation structure comprising polyimide located between dies. Further, the isolation structure of embodiments of the present disclosure, due to its inclusion of polyimide, exhibits excellent electrical isolation properties, provides good electrical isolation effect even applied to substrates made of silicon carbide, and is suitable for high-voltage products (e.g., high-voltage components ranging from 650 to 1200 V or 1500 V). Furthermore, the isolation structure of embodiments of the present disclosure is not only formed within the substrate and epitaxial layer, but also extends beyond the bottom surface of the substrate and epitaxial layer. The portion of the isolation structure located outside the substrate and epitaxial layer has a width greater than the portion of the isolation structure located within the substrate and epitaxial layer, and is formed in a configuration similar to a round iron nail or a thumbtack. This effectively prevents the adhesion issues caused by the stress difference between the dissimilar dielectric materials of polyimide and silicon carbide, thereby achieving excellent product durability.

The semiconductor devices/structures of embodiments of the present disclosure are described in a coordinate system including an X-direction, a Y-direction and a Z-direction perpendicular to each other. The Z-direction represents the vertical direction, i.e., in the top-bottom direction of a semiconductor device. The Z-direction is perpendicular to a plane formed by the X-direction and the Y-direction. The X-direction is in the width direction of the semiconductor device. The Y-direction is in the length direction of the semiconductor device. The plane formed by the X-direction and the Y-direction is parallel to (or substantially parallel to) the top surface (or bottom surface) of a substrate of the semiconductor device.

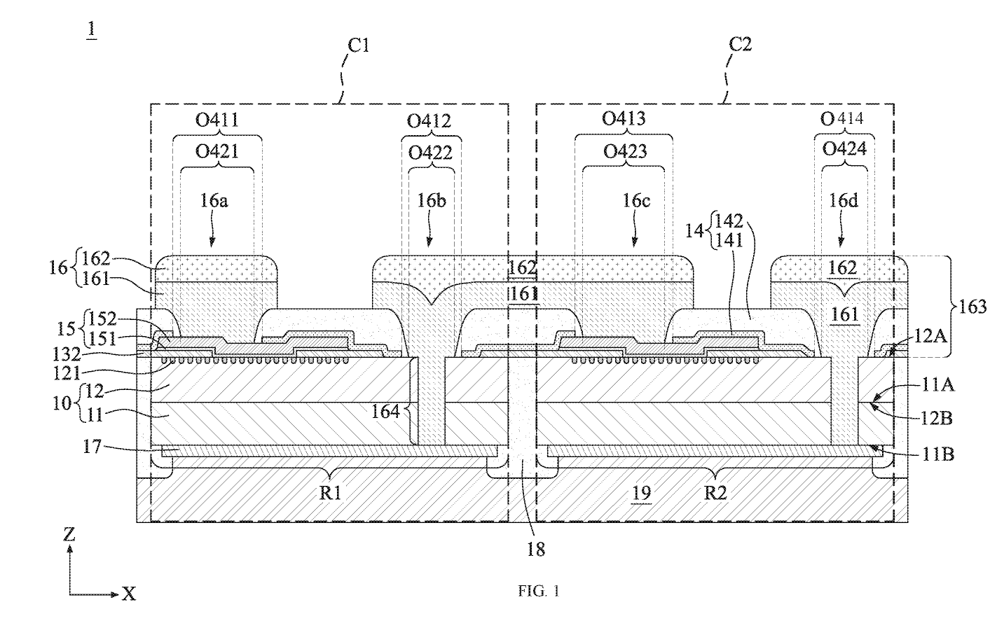

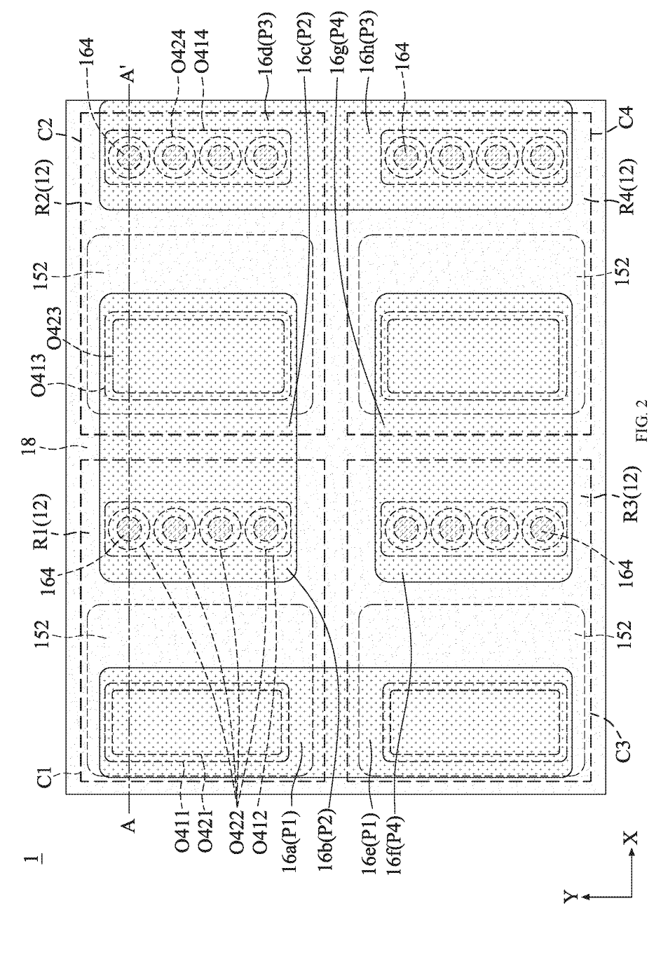

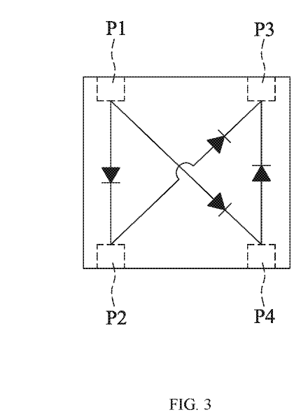

FIGS. 1, 2 and 3 are schematic diagrams of a semiconductor device 1 according to embodiments of the present disclosure. FIG. 1 is a cross-sectional view of the semiconductor device 1 taken along a line AA' in FIG. 2. FIG. 2 is a top view of the semiconductor device 1. FIG. 3 is a circuit layout diagram of the semiconductor device 1. FIG. 3 shows a circuit of a bridge rectifier that may be implemented by the semiconductor device 1. At least some of these figures have been simplified to facilitate a better understanding of aspects of the present disclosure. The semiconductor device 1 may be a bridge rectifier device.

Referring to FIGS. 1 and 2, the semiconductor device 1 includes multiple semiconductor dies, such as a first die C1 shown in FIG. 1, a second die C2 adjacent to the first die C1 along a first horizontal direction (e.g., the X-direction), a third die C3 adjacent to the first die C1 along a second horizontal direction (e.g., the Y-direction), and a fourth die C4 adjacent to the third die C3 along the first horizontal direction (i.e., the X-direction) and adjacent to the second die C2 along the second horizontal direction (i.e., the Y-direction). Each of the semiconductor dies C1, C2, C3, and C4 includes a portion of a substrate and epitaxial layer 10. In other words, the substrate and epitaxial layer 10 are divided into multiple regions during a manufacturing process, such as a first region R1 and a second region R2 in FIG. 1, and a third region R3 and a fourth region R4 in FIG. 2. The multiple regions R1, R2, R3, and R4 correspond to the multiple semiconductor dies C1, C2, C3, and C4, respectively, and the multiple regions R1, R2, R3, and R4 are separated by an isolation structure 18. The multiple semiconductor dies C1, C2, C3, and C4 may have similar structures. For illustrative purposes, the first die C1 is mainly used in the following description.

In some embodiments, the semiconductor device 1 includes the substrate and epitaxial layer 10. The substrate and epitaxial layer 10 includes a substrate and an epitaxial layer disposed on the substrate (which are herein collectively referred to as a substrate and epitaxial layer). The substrate and epitaxial layer 10 may include a plurality of regions that are separated by the isolation structure 18. In some embodiments, the plurality of regions may be arranged in rows and columns (e.g., in a plane defined by the X-direction and the Y-direction), with the isolation structure 18 arranged between the rows and the columns separating the regions. There may be one semiconductor die formed in each of the plurality of regions. The semiconductor dies formed in the plurality of regions may have similar structures. Each of the semiconductor dies may include a portion of the substrate and epitaxial layer 10.

In the example embodiments described in the following, the substrate and epitaxial layer 10 includes the four regions R1-R4, arranged in two rows and two columns on the X-Y plane. The four semiconductor dies C1-C4 are formed in the four regions R1-R4 respectively, and have similar structures. In the following, the first die C1 and the first region R1 are used as an example for illustration purposes. The descriptions apply similarly to other dies and their corresponding regions.

Referring to FIG. 1, the first die C1 in the first region R1 includes the substrate and epitaxial layer 10, a rectifier structure 15 disposed on a top surface 12A of the substrate and epitaxial layer 10, a first electrode 16a disposed on the rectifier structure 15, and a second electrode 16b extending from above the top surface 12A of the substrate and epitaxial layer 10 toward a bottom surface 11B of the substrate and epitaxial layer 10.

The substrate and epitaxial layer 10 has the top surface 12A and the bottom surface 11B opposite to the top surface 12A. In some embodiments, the top surface 12A and the bottom surface 11B may be horizontal. For illustrative convenience, the direction perpendicular to the top surface 12A and the bottom surface 11B is defined as the vertical direction (e.g., the Z-direction), and the direction perpendicular to the vertical direction is defined as the horizontal direction (e.g., the X-direction and the Y-direction). The substrate and epitaxial layer 10 includes a substrate 11 and an epitaxial layer 12 stacked vertically on the substrate 11. In some embodiments, the substrate 11 may be a portion of a silicon carbide wafer. In some embodiments, the bottom surface of the substrate 11 defines the bottom surface 11B of the substrate and epitaxial layer 10. For illustrative convenience, the bottom surface of the substrate 11 and the bottom surface of the substrate and epitaxial layer 10 share the reference numeral 11B. The substrate 11 also has a top surface 11A opposite to the bottom surface 11B, and the epitaxial layer 12 is disposed on the top surface 11A of the substrate 11. In some embodiments, the bottom surface 12B of the epitaxial layer 12 contacts the top surface 11A of the substrate 11. The epitaxial layer 12 also has a top surface opposite to the bottom surface 12B, and in some embodiments, the top surface of the epitaxial layer 12 defines the top surface 12A of the substrate and epitaxial layer 10. For illustrative convenience, the top surface of the epitaxial layer 12 shares the same reference numeral 12A with the top surface of the substrate and epitaxial layer 10.

The substrate and epitaxial layer 10 may have different doping conductivity types as needed. For example, the substrate and epitaxial layer 10 may include a P-type doped region configured for an N-type transistor or an N-type doped region configured for a P-type transistor. The N-type doped region is doped with an N-type dopant, such as phosphorus, arsenic, other N-type dopants, or a combination thereof. The P-type doped region is doped with a P-type dopant, such as boron, indium, other P-type dopants, or a combination thereof. The N-type or P-type doped region may be formed by performing an ion implantation process, a diffusion process, and/or other suitable doping processes. The substrate 11 and epitaxial layer 12 have the same conductivity type, e.g., they both are N-type or P-type. In some embodiments, the doping concentration of the substrate 11 may be greater than the doping concentration of the epitaxial layer 12. For illustrative convenience, N-type is referred to as a first conductivity type and P-type is referred to as a second conductivity type, and the substrate and epitaxial layer 10 is described using the first conductivity type as an example. However, the present disclosure is not limited thereto. The N-type (first type) or P-type (second type) substrate and epitaxial layer 10 may be adjusted based on the conductivity type of the semiconductor device 1. Whether substrate and epitaxial layer 10 may be of N-type (the first conductivity type) or P-type (the second conductivity type) may be adjusted according to the conductivity type of the semiconductor device 1.

The first die C1 may include a cell region located in a central area and a termination region located in a peripheral area and surrounding the cell region. For the purpose of simplifying the drawings, the cell region and the termination region are not indicated by symbols in FIG. 1.

In an example, the cell region may be located within the first region R1 (e.g., in the middle of the first region R1), and the termination region may be located in the first region R1, surrounding the cell region and adjoining the cell region. In another example, the cell region may not be centered in the first region R1.

The epitaxial layer 12 includes a plurality of doped regions 121 located in the cell region and in a portion of the termination region adjoining the cell region. The doped regions 121 extend from the top surface 12A of the epitaxial layer 12 toward the bottom surface 12B of the epitaxial layer 12, and the doped regions 121 have a depth that is less than the thickness of the epitaxial layer 12. In some embodiments, adjacent doped regions 121 are separated from each other. In some embodiments, the doped regions 121 have the second conductivity type that is different from the first conductivity type. The doped regions 121 may be arranged and spaced apart along the X-direction.

The rectifier structure 15 is disposed on the top surface 12A of the substrate and epitaxial layer 10. In some embodiments, each region (e.g., the first region R1) of the four regions R1-R4 has one rectifier structure 15. In some embodiments, the rectifier structure 15 includes a first metal layer 151 and a second metal layer 152. In some embodiments, the first metal layer 151 contacts the top surface 12A of a portion of the epitaxial layer 12 located in the cell region. In some embodiments, the first metal layer 151 covers a portion of the epitaxial layer 12 located in the termination region adjacent to the cell region. In some embodiments, the first metal layer 151 and the portion of the epitaxial layer 12 located in the termination region are separated from each other. The first metal layer 151 and the portion of the epitaxial layer 12 located in the termination region are separated, for example, by a dielectric layer 132.

In some embodiments, the first metal layer 151 may include three portions, i.e., a first portion, a second portion connected to the first portion, and a third portion connected to the second portion. The second portion may be in contact with a portion of the top surface 12A of the epitaxial layer 12 located in the cell region. That is, the second portion of the first metal layer 151 is located in the cell region and may be contact with the top surface 12A of the epitaxial layer 12. The first portion and the third portion of the first metal layer 151 are located in the termination region above the epitaxial layer 12, without contacting the top surface 12A of the epitaxial layer 12. In some embodiments, the dielectric layer 132 is disposed between the first portion and the epitaxial layer 12, and between the third portion of the first metal layer 151 and the epitaxial layer 12. The dielectric layer 132 may be in contact with the first portion, the third portion, and a portion of the top surface 12A of the epitaxial layer 12. In some embodiments, the first metal layer 151 covers the doped regions 121 in the epitaxial layer 12. The second metal layer 152 is disposed on and in contact with the first metal layer 151. The second metal layer 152 may be conformally disposed on the first metal layer 151. In some embodiments, the second metal layer 152 has a thickness greater than that of the first metal layer 151. The rectifier structure 15 may not cover the entire portion of the substrate and epitaxial layer 10 in the first region R1.

In some embodiments, the first metal layer 151 and the second metal layer 152 may be made of different metal materials. In some embodiments, the first metal layer 151 is made of titanium, indium, aluminum, gallium, an alloy thereof, or a combination thereof. In some embodiments, the second metal layer 152 is made of tungsten, copper, or aluminum. In some embodiments, the first metal layer 151 serves as a Schottky metal layer of the rectifier structure 15. The first metal layer 151 contacts the top surface 12A of the epitaxial layer 12 to form a Schottky junction. For example, the second portion of the first metal layer 151 in contact with the top surface 12A of the epitaxial layer 12 forms a Schottky junction. In some embodiments, the second metal layer 152 serves as a conductive structure to provide electrical connections between other conductive pads or conductive lines and the first metal layer 151.

Each of the semiconductor dies C1-C4 may have a plurality of electrodes, which are collectively referred to as electrodes 16. Each electrode is represented by a reference symbol “16x”, where x represents a lowercase letter. For example, the first die C1 has a first electrode 16a and a second electrode 16b, which are separated from each other. Similarly, the second die C2 has electrodes 16c and 16d, the third die C3 has electrodes 16e and 16f, and the fourth die C4 has electrodes 16g and 16h. Taking the first die C1 as an example, the first electrode 16a is located over and electrically connected to the rectifier structure 15. In some embodiments, the first electrode 16a contacts the second metal layer 152. The second electrode 16b extends from above the top surface 12A of the substrate and epitaxial layer 10 toward the bottom surface 11B, extending through the substrate and epitaxial layer 10. Specifically, the second electrode 16b has a vertical portion 164 that penetrates the substrate 11 and epitaxial layer 12 to electrically connect to a metal layer 17 located on the bottom surface 11B of the substrate 11. In some embodiments, the second electrode 16b contacts the metal layer 17. The second electrode 16b has another portion 163 extending from the top surface 12A of the substrate and epitaxial layer 10 away from the substrate and epitaxial layer. The portions 163 and 164 are connected at the top surface 12A of the substrate and epitaxial layer 10. That is, the portion 163 is outside of the substrate and epitaxial layer 10, and the vertical portion 164 is inside the substrate and epitaxial layer 10. The first electrode 16a may also be considered as only including a portion 163 that is over the top surface 12A of the substrate and epitaxial layer 10. The second electrode 16b does not overlap with the rectifier structure 15 in the top view of the semiconductor device 1. When the first die C1 is in operation, the first electrode 16a and the second electrode 16b function as an anode and a cathode, respectively. For example, the first electrode 16a functions as an anode, and the second electrode 16b functions as a cathode. In the following, the electrodes 16a, 16c, 16e and 16g may also be referred to respectively as anodes 16a, 16c, 16e and 16g, and the electrodes 16b, 16d, 16f and 16h may also be referred to respectively as cathodes 16b, 16d, 16f and 16h.

The first electrode 16a and the second electrode 16b may each be a single metal layer conductive structure, or a multi-layer conductive structure comprising different metal materials. In some embodiments, the first electrode 16a includes a first conductive material layer 161 and a second conductive material layer 162 located on the first conductive material layer 161. In some embodiments, the first conductive material layer 161 includes copper and the second conductive material layer 162 includes tin, however, the present disclosure is not limited thereto. The first conductive material layer 161 and the second conductive material layer 162 may include other applicable metal materials, such as tungsten, titanium, platinum, tantalum, and so on. In the embodiments of the present disclosure, the semiconductor device 1 does not include lead. That is, no component of the semiconductor device 1 uses lead. A portion of the first conductive material layer 161 may be in contact with the rectifier structure 15.

In some embodiments, for ease of manufacturing, the second electrode 16b may have a single or multi-layer structure similar to the first electrode 16a. For example, the second electrode 16b may include the first conductive material layer 161 and the second conductive material layer 162 located on the first conductive material layer 161. In some embodiments, the first conductive material layer 161 of the second electrode 16b extends over the top surface 12A of the substrate and epitaxial layer 10, covering a portion of the first region R1, and extends from the top surface 12A toward the bottom surface 12B, penetrating vertically the first region R1 of the substrate and epitaxial layer 10. In some embodiments, the second conductive material layer 162 of the second electrode 16b is located on the first conductive material layer 161 that is on the top surface 12A of the substrate and epitaxial layer 10, and is separated from the top surface 12A of the substrate and epitaxial layer 10.

In other words, the second electrode 16b extends from the bottom surface of the 11B of the substrate 11 toward the top surface 12A of the epitaxial layer 12, and extends through the substrate and epitaxial layer 10 and beyond the top surface 12A of the epitaxial layer 12. In an example, the first conductive material layer 161 of the second electrode 16b extends from the bottom surface of the 11B of the substrate 11, through the substrate and epitaxial layer 10, and out of the top surface 12A of the epitaxial layer 12. The second conductive material layer 162 of the second electrode 16b is disposed on a top surface of the first conductive material layer 161 above the top surface 12A of the epitaxial layer 12. The top surface of the first electrode 16a may be coplanar with the top surface of the second electrode 16b.

In some embodiments, each die of C1-C4 may include multiple electrodes, and each of the electrodes may be in a multi-layer conductive structure comprising different conductive material layers disposed with one conductive material layer on the other, such as the first conductive material layer 161 and the second conductive material layer 162. Each of the electrodes may be considered as including a portion of the first conductive material layer 161 and a portion of the second conductive material layer 162.

To reduce leakage current, a portion of the first electrode 16a not in contact with the rectifier structure 15 is separated from the top surface 12A of the substrate and epitaxial layer 10 by a dielectric structure 14, and a portion of the second electrode 16b located above the top surface 12A of the substrate and epitaxial layer 10 is separated from the top surface 12A of the substrate and epitaxial layer 10 by the dielectric structure 14. To adapt to the market trend of shrinking product sizes, a dielectric material with good dielectric effect may be selected for the dielectric structure 14. In addition, to achieve good adhesion effect and reduce the problem of easy shedding between different dielectrics, the dielectric structure 14 may have multiple layers of materials. For example, the dielectric structure 14 may include a first passivation layer 141 conformally disposed on the substrate and epitaxial layer 10, the dielectric layer 132 and the rectifier structure 15, and a second passivation layer 142 covering the first passivation layer 141. The first passivation layer 141 may cover only a portion of the rectifier structure 15.

The first passivation layer 141 and the second passivation layer 142 may be made of the same dielectric material or different dielectric materials (depending on different embodiments, the first passivation layer 141 and the second passivation layer 142 may also be referred to as a dielectric layer 141 and a dielectric layer 142. To distinguish them from the dielectric layer 132, the first passivation layer 141 and the second passivation layer 142 will be referred to below). In some embodiments, to ensure effective leakage protection even in micro-sized products, the second passivation layer 142 may be made of polyimide. Because polyimide is subject to significant stress and may pull on the underlying metal material during the manufacturing process, the first passivation layer 141 may selectively be made of a different dielectric material to mitigate deformation or peeling caused by stress differences. In some embodiments, the first passivation layer 141 is made of silicon nitride, silicon oxide, or a combination thereof.

The first die C1 further includes the metal layer 17 disposed on the bottom surface 11B of the substrate 11. The metal layer 17 is electrically connected to the second electrode 16b, and is connected to an external voltage, serving as the cathode of the first die C1. In some embodiments, the metal layer 17 is considered part of the cathode of the first die C1. Furthermore, to protect the metal layer 17, the first die C1 may further include a molding material layer 19 disposed on the bottom surface 11B of the substrate 11 and covering the metal layer 17. In some embodiments, the molding material layer 19 has a flat surface facing away from the metal layer 17. The molding material layer 19 may be disposed on the metal layer 17 and the bottom surface 11B of the substrate 11. The metal layer 17 covers the second electrode 16b extended to the bottom surface 11B of the substrate 11. The vertical portion 164 of the second electrode 16b is exposed from the bottom surface 11B of the substrate 11, but covered by the metal layer 17.

As described above, the semiconductor dies C1, C2, C3, and C4 have similar structures. The substrates and epitaxial layers 10 of the adjacent semiconductor dies C1, C2, C3, and C4 are separated by the isolation structure 18. The isolation structure 18 separates and isolates the regions R1-R4, and the corresponding semiconductor dies C1, C2, C3, and C4. For example, as shown in FIG. 1, the isolation structure 18 is located between the first region R1 and the second region R2. As another example, as shown in FIG. 2, the isolation structure 18 surrounds each of the semiconductor dies C1, C2, C3 and C4. The isolation structure 18 extends from the top surface 12A of the substrate and epitaxial layer 10 toward the bottom surface 11B of the substrate and epitaxial layer 10, and protrudes beyond the bottom surface 11B. The isolation structure 18 is made of a dielectric material, such as polyimide. The isolation structure 18 and the substrate and epitaxial layer 10 may have the problem of insufficient adhesion between different dielectric materials. To prevent problems such as peeling or delamination, in the embodiments of the present disclosure, the portion of the isolation structure 18 protruding from the bottom surface 11B has a larger width. The detailed structure of the isolation structure 18 will be described in the following.

To achieve the circuit layout shown in FIG. 3 such that the semiconductor dies C1, C2, C3, and C4 are electrically connected to function as a bridge rectifier, the cathode of the first die C1 and the anode of the second die C2 shown in FIG. 1 need to be electrically connected. As shown in FIG. 1, the second die C2 has two electrodes 16c and 16d, which serve respectively as the anode and cathode of the second die C2. For illustrative convenience, the first electrode 16a of the first die C1 is referred to as an anode 16a, and the second electrode 16b of the first die C1 is referred to as a cathode 16b. Furthermore, the electrode 16c of the second die C2 is referred to as an anode 16c, and the electrode 16d is referred to as an cathode 16d.

The cathode 16b of the first die C1 and the anode 16c of the second die C2 are adjacent, and they may be electrically connected to each other directly via the first conductive material layer 161 and the second conductive material layer 162. As can be seen from the cross-sectional view of FIG. 1 and the top view of FIG. 2, the cathode 16b of the first die C1 and the anode 16c of the second die C2 each include a portion of the first conductive material layer 161 and a portion of the second conductive material layer 162. The portion of the first conductive material layer 161 of the cathode 16b located in the first region R1 contacts the portion of the first conductive material layer 161 of the anode 16c located in the second region R2, and the portion of the second conductive material layer 162 of the cathode 16b located in the first region R1 contacts the portion of the second conductive material layer 162 of the anode 16c located in the second region R2.

Referring to FIG. 2, the cathode 16b of the first die C1 and the anode 16c of the second die C2 are connected along the first horizontal direction (X-direction), together forming an electrode pad P2. Similarly, the anode 16a of the first die C1 and the anode 16e of the third die C3 are adjacent along the second horizontal direction (Y-direction) and may therefore be directly electrically connected via the first conductive material layer 161 and the second conductive material layer 162, together forming an electrode pad P1. The cathode 16f of the third die C3 and the anode 16g of the fourth die C4 are adjacent along the first horizontal direction and may therefore be directly electrically connected via the first conductive material layer 161 and the second conductive material layer 162, together forming an electrode pad P4. The cathode 16h of the fourth die C4 and the cathode 16d of the second die C2 are adjacent along the second horizontal direction and may therefore be directly electrically connected via the first conductive material layer 161 and the second conductive material layer 162, together forming an electrode pad P3.

The electrode pad P2 includes the cathode 16b of the first die C1, and therefore includes the portion 163 located over the top surface 12A of the substrate and epitaxial layer 10, and the portion 164 located below the top surface 12A of the substrate and epitaxial layer 10. Generally speaking, the portion 163 may be considered as extending horizontally and is therefore referred to as a horizontal portion 163, and the portion 164 extends vertically and is therefore referred to as a vertical portion 164. Similarly, the electrode pads P3 and P4 also have the horizontal portions 163 and the vertical portions 164. Since electrode pad P1 only includes the anode 16a of the first die C1 and the anode 16e of the third die C3, it does not have the vertical portion 164 located below the top surface 12A of the substrate and epitaxial layer 10, and only has the horizontal portion 163 located over the top surface 12A of the substrate and epitaxial layer 10.

FIG. 2 shows the top view of the semiconductor device 1 with emphasis on the electrodes 16. In the top view, the electrodes 16a, 16c, 16e and 16g each extend in the X-direction and the Y-direction, and may each be in a rectangular shape. In an example as shown in FIG. 2, the electrode 16b may include multiple vertical portions 164, each of which is in a cylindrical shape within the substrate and epitaxial layer 10. The vertical portions 164 may extend along the Y-direction and be spaced apart. The electrodes 16d, 16f and 16h each may also have the similar structure of the multiple vertical portions 164. FIGS. 1 and 2 also show positions of openings O411-O414 formed by the first passivation layer 141 and O421-O424 formed by the second passivation layer 141 , which will be described later.

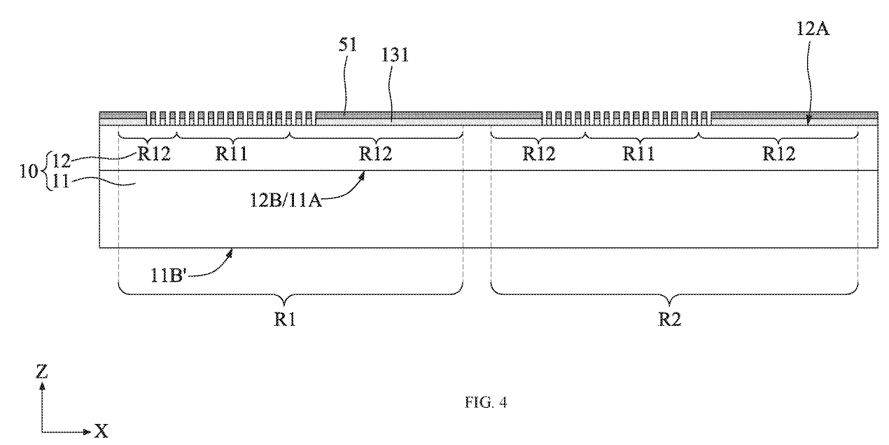

FIGS. 4-19 illustrate one or more stages in a manufacturing method of a semiconductor device 2 according to certain embodiments of the present disclosure. The structure of the semiconductor device 2 is similar to that of the semiconductor device 1 shown in FIGS. 1 and 2. At least some of these figures have been simplified to facilitate a better understanding of aspects of the present disclosure. FIGS. 4-19 are cross-sectional views of the semiconductor device 2 in various stages of manufacturing the semiconductor device 2. Although only two regions R1 and R2 are shown, the method applies similarly to other regions. The steps described below may similarly be applied to each of the regions of the substrate and epitaxial layer 10 divided for forming corresponding semiconductor dies and isolated by the isolation structure 18.

Referring to FIG. 4, the manufacturing method of the semiconductor device 2 includes forming the substrate and epitaxial layer 10, and forming a patterned mask layer 131 on the top surface 12A of the substrate and epitaxial layer 10, which serves as a mask for forming the multiple doped regions 121 in the substrate and epitaxial layer 10 in subsequent steps. The substrate and epitaxial layer 10 may include multiple silicon carbide layers 11 having different doping concentrations, for example, the substrate 11 and the epitaxial layer 12 located on the top surface 11A of the substrate 11. In some embodiments, the substrate 11 is epitaxially grown on the top surface of a silicon wafer, and the silicon wafer is then removed. In some embodiments, the substrate 11 may be the entirety of a silicon carbide wafer or a portion of the silicon carbide wafer near the top surface of the silicon carbide wafer. In some embodiments, the epitaxial layer 12 is epitaxially grown on the top surface 11A of the substrate 11. The substrate 11 and the epitaxial layer 12 have the same conductivity type, for example, N-type, and the doping concentration of the substrate 11 is greater than that of the epitaxial layer 12. In some embodiments, the doping concentration of the substrate 11 ranges from 1E17 to 1E19 atoms/cm³. In some embodiments, the doping concentration of the epitaxial layer 12 is in a range from 8E15 to 1.5E16 atoms/cm3. It should be noted that since the substrate 11 may be thinned in subsequent manufacturing steps, the bottom surface 11B' of the substrate 11 in the step shown in FIG. 4 is different from the bottom surface 11B shown in FIG. 1.

In an embodiment where the substrate 11 is epitaxially grown, ions with N-type electrical properties are introduced during the epitaxial growth to form the N-type substrate 11 without the need for additional ion implantation. In an embodiment of using the silicon carbide wafer as the substrate 11, the N-type substrate 11 may be formed by ion implantation. Similarly, in some embodiments, ions with N-type electrical properties are introduced during the epitaxial growth to form the N-type epitaxial layer 12, without the need for additional ion implantation. In some embodiments, ions with N-type electrical properties are uniformly introduced during the epitaxial growth process to form the substrate 11 or the epitaxial layer 12 with a uniform doping concentration, where the concentration of the ions introduced during the epitaxial growth process does not change over time. In some embodiments, the epitaxial layer 12 may have a doping concentration gradient that increases from the top surface 12A of the epitaxial layer 12 to its bottom surface 12B. In some embodiments, the increasing doping concentration gradient may be adjusted according to the withstand voltage and resistance required by the product. In some embodiments, ions with N-type electrical properties are introduced during the epitaxial growth process, where the concentration of the introduced ions decreases over time, thereby forming the epitaxial layer 12 having the doping concentration that increases from the top surface 12A to the bottom surface 12B. Similarly, the substrate 11 may also have a doping concentration that increases from the top surface 11A to the bottom surface 11B', as needed. Regardless of whether the substrate 11 or the epitaxial layer 12 has a uniform or non-uniform doping concentration, the doping concentration of the substrate 11 is still greater than the doping concentration of the epitaxial layer 12. In some embodiments, the substrate and epitaxial layer 10 has a doping concentration that increases from the top surface 12A to the bottom surface 11B'.

The substrate and epitaxial layer 10 is divided into multiple regions, such as the first region R1 and the second region R2, which respectively represent the locations of the first die C1 and the second die C2 to be formed later. In each of the regions R1 and R2, a cell region R11, and a termination region R12 surrounding and adjoining the cell region R11 are defined. In other words, each region R1 or R2 is divided into the cell region R11 and the termination region R12. As an example as shown in FIG. 4, the cell region R11 may not be centered along the X-direction in each of the regions R1 and R2. Thus, in the cross-sectional view of FIG. 4, the termination region R12 at opposing sides of the cell region R11 has different widths along the X-direction. The patterned mask layer 131 may be a dielectric layer, whose material is, for example, an oxide. In some embodiments, a dielectric layer is formed on the top surface 12A of the epitaxial layer 12, and then a patterned photoresist layer 51 is formed on the dielectric layer. The dielectric layer is then etched using the patterned photoresist layer 51 as a mask to form the patterned mask layer 131. The patterned mask layer 131 has multiple openings located in the first region R1 and multiple openings located in the second region R2. The multiple openings in the patterned mask layer 131 define the locations of the doped regions 121 to be formed in subsequent steps. The openings in the patterned mask layer 131 expose portions of the top surface 12A of the epitaxial layer 12 in the regions R1 and R2. In each of the regions R1 and R2, a portion of the openings of the patterned mask layer 131 may be located in the cell region R11, and a portion of the openings of the patterned mask layer 131 may be located in a portion of the terminal region R12 that adjoining the cell region R11. The openings may be evenly distributed along the X-direction.

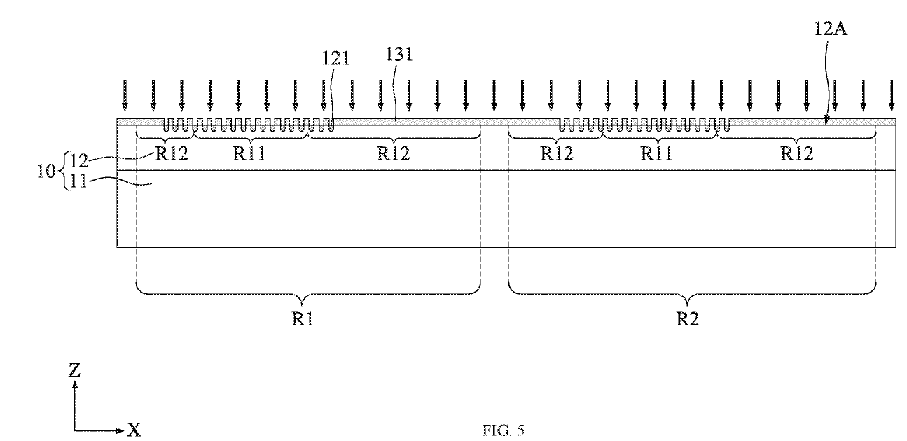

Referring to FIG. 5, the manufacturing method of the semiconductor device 2 includes performing ion implantation on the substrate and epitaxial layer 10 using the patterned mask layer 131 as a mask to form the plurality of doped regions 121 in the epitaxial layer 12 adjacent to the top surface 12A of the substrate and epitaxial layer 10. The doped regions 121 extend from the top surface 12A of the substrate and epitaxial layer 10 into the epitaxial layer 12. In some embodiments, the patterned photoresist layer 51 is removed prior to performing the ion implantation. The doped regions 121 have a different conductivity type than the epitaxial layer 12, e.g., the doped regions 121 are of P-type. In some embodiments, the ion implantation may be performed in a high temperature environment, e.g., in an environment where the temperature ranges from 450^{o}C to 600^{o}C. In some embodiments, aluminum ions are used in the ion implantation.

The doped regions 121 are distributed in the cell region R11 of the first region R1 and the termination region R12 adjacent to the cell region R11 of the first region R1, and are also distributed within the cell region R11 of the second region R2 and the termination region R12 adjacent to the cell region R11 of the second region R2 (although not shown in the drawings, it may be understood that the termination region R12 surrounds the cell region R11). After forming the doped regions 121, the patterned mask layer 131 is removed. In some embodiments, after removing the patterned mask layer 131, a thermal annealing step is performed on the substrate and epitaxial layer 10 to activate the doping ions in the doped regions 121. In some embodiments, the temperature of the thermal annealing step ranges from 1600^{o} C to 1700^{o} C. In some embodiments, before the thermal annealing step is performed, a carbon-containing layer may selectively be formed on the top surface 12A of the substrate and epitaxial layer 10 to protect the substrate and epitaxial layer 10 during the thermal annealing step.

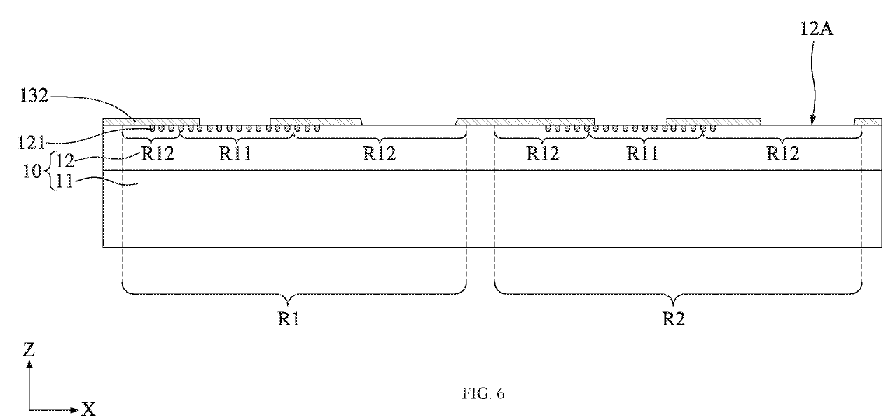

Referring to FIG. 6, the manufacturing method of the semiconductor device 2 includes forming the dielectric layer 132 on the top surface 12A of the substrate and epitaxial layer 10. The dielectric layer 132 covers the termination region R12 and a portion of the cell region R11 adjacent to the termination region R12. Specifically, the dielectric layer 132 covers at least a portion of the substrate and epitaxial layer 10 adjacent to the junction of the termination region R12 and the cell region R11. In some embodiments, the dielectric layer 132 covers portions of the substrate and epitaxial layer 10 that is located in a region where the cell region R11 adjoins the termination region R12. The dielectric layer 132 may have openings exposing a portion of the cell region R11 and a portion of the termination region R12. For example, a middle portion of the cell region R11 may be exposed. A portion of the termination region R12 away from the cell region R11 may also be exposed.

The rectifier structure 15 will be formed subsequently which may be configured to contact a portion of the substrate and epitaxial layer 10 in the cell region R11, and at least a portion of the substrate and epitaxial layer 10 in the cell region R11 is exposed from the dielectric layer 132 for this purpose. That is, a portion of the cell region R11 is exposed by the dielectric layer 132. Further, to prevent the Schottky junction formed by the rectifier structure 15 contacting the substrate and epitaxial layer 10 from being too close to the termination region R12, which causes leakage current and reduces the withstand voltage of the semiconductor structure 2, the dielectric layer 132 may cover a portion of the substrate and epitaxial layer 10 adjacent to the junction of the cell region R11 and the termination region R12. Furthermore, the dielectric layer 132 exposes a portion of the substrate and epitaxial layer 10 located in the termination region R12 and away from the interface between the cell region R11 and the termination region R12 (away from the region where cell region R11 and the termination region R12 adjoin), thereby preserving an opening required for forming the vertical portion 164 of the cathode electrode in subsequent steps. In some embodiments, the dielectric layer 132 covers at least all of the doped regions 121 located in the termination region R12. Generally, the configuration of the dielectric layer 132, such as the positions and openings exposing the substrate and epitaxial layer 10, may be determined in consideration of forming subsequently the rectifier structure 15 and the cathode electrode.

The dielectric layer 132 may be formed by a deposition method, and then patterned to define the positions of the rectifier structure 15 and the vertical portion 164 of the cathode, whereby the dielectric layer 132 as shown in FIG. 6 is formed. The patterning may be, for example, forming a photoresist layer on the unpatterned dielectric layer 132 and removing the photoresist layer after patterning.

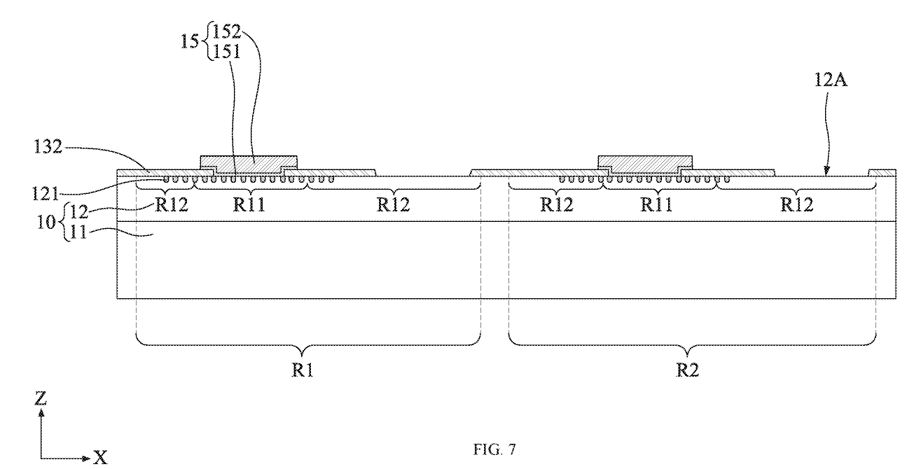

Referring to FIG. 7, the manufacturing method of the semiconductor device 2 includes forming the rectifier structure 15 in the cell region R11, where the rectifier structure 15 covers at least the cell region R11 exposed by the dielectric layer 132. In some embodiments, the rectifier structure 15 contacts the portion of the substrate and epitaxial layer 10 located in the cell region R11 and exposed by the dielectric layer 132. In some embodiments, the rectifier structure 15 further covers a portion of the dielectric layer 132. In some embodiments, the rectifier structure 15 contacts the top surface 12A of the portion of the substrate and epitaxial layer 10 located in the cell region R11 and exposed by the dielectric layer 132, and covers a portion of the dielectric layer 132 around the exposed portion of the substrate and epitaxial layer 10.

In some embodiments, the rectifier structure 15 includes a first metal layer 151 and a second metal layer 152 covering the first metal layer 151. In some embodiments, the first metal layer 151 contacts the top surface 12A of the portion of the epitaxial layer 12 located in the cell region R11 (exposed by the dielectric layer 132). In some embodiments, multiple deposition or sputtering steps are performed to form the first and second metal layers 151 and 152, followed by an etching step. In some embodiments, the edges of the first and second metal layers 151 and 152 are aligned. Depending on different embodiments, the rectifier structure 15 may or may not cover the termination region R12. For example, in the embodiment shown in the cross-sectional view of FIG. 1 and the top view of FIG. 2, the second metal layer 152 covers most of the die area (including the cell region R11 and the termination region R12, in other words, the rectifier structure 15 covers the entire cell region R11 and most of the termination region R12) except for the vertical portion 164. For another example, referring to the embodiment shown in FIG. 7, the rectifier structure 15 only covers the cell region R11. In some embodiments, after forming the first metal layer 151 and before forming the second metal layer 152, a thermal annealing step may be performed on the first metal layer 151, which can help reduce issues of current leakage.

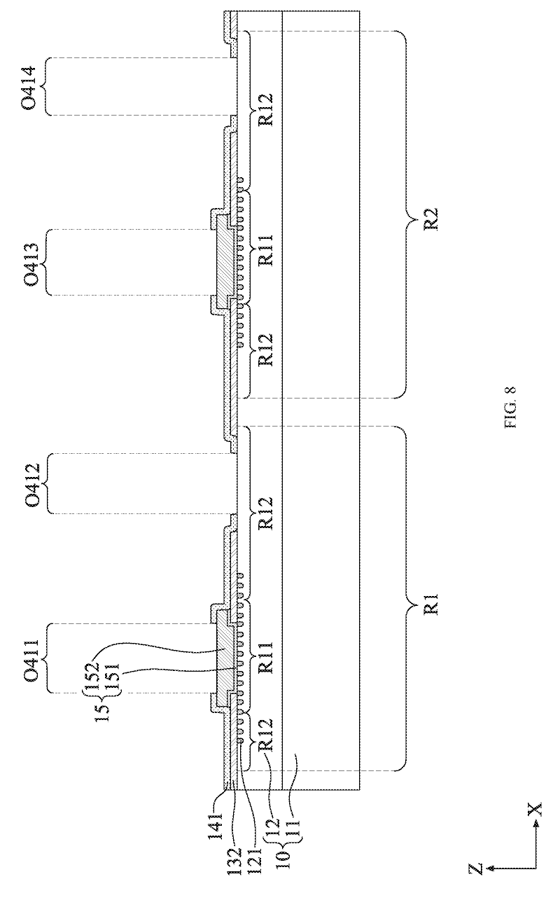

Referring to FIG. 8, the manufacturing method of the semiconductor device 2 includes forming the first passivation layer 141 covering the rectifier structure 15 and the dielectric layer 132. The first passivation layer 141 my cover a portion of the rectifier structure 15, i.e., exposing partially the top surface of the second metal layer 152. In some embodiments, the material of the first passivation layer 141 includes silicon nitride, silicon oxide, or a combination thereof, serving as an adhesion layer between the subsequently formed second passivation layer 142 and the underlying material. The first passivation layer 141 may be formed by chemical vapor deposition (CVD), physical vapor deposition (PVD), or a combination thereof. The first passivation layer 141 has multiple openings in each region (R1 or R2) to define the locations of the anode contact and cathode contact to be formed later. For example, the first passivation layer 141 has an opening O411 and an opening O412 in the first region R1. The opening O411 exposes a portion of the rectifier structure 15 in the cell region R11, and the opening O412 exposes a portion of the substrate and epitaxial layer 10 in the termination region R12, away from the doped regions 121. For another example, the first passivation layer 141 has an opening O413 and an opening O414 in the second region R2. The opening O413 exposes a portion of the rectifier structure 15 in the cell region R11, and the opening O414 exposes a portion of the substrate and epitaxial layer 10 in the termination region R12 away from the doped regions 121.

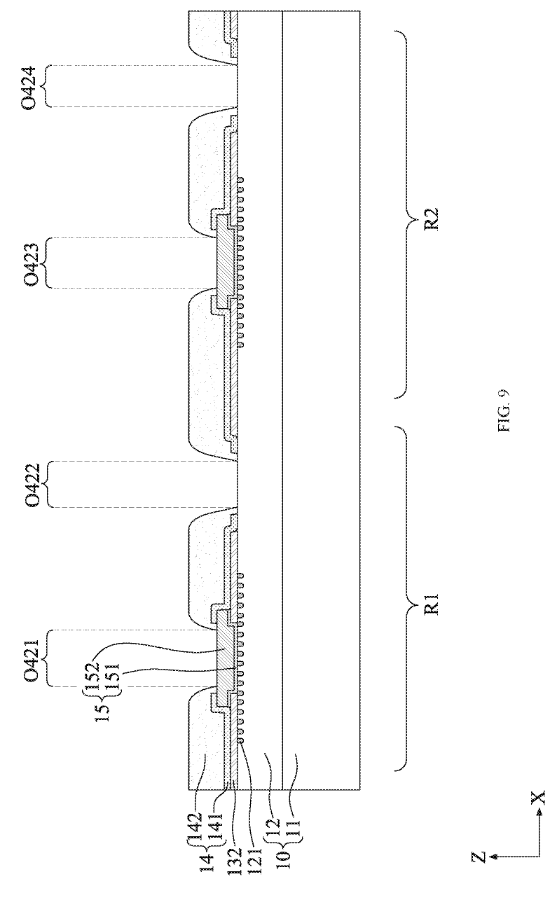

Referring to FIG. 9, the manufacturing method of the semiconductor device 2 includes forming the second passivation layer 142 covering the first passivation layer 141. The first passivation layer 141 and the second passivation layer 142 constitute the dielectric structure 14. The second passivation layer 142 is configured to electrically isolate the anode and cathode, which will be formed later, from the rectifier structure 15 and the substrate and epitaxial layer 10, respectively. Therefore, the second passivation layer 142 also has multiple openings to define the locations of the anode contact and the cathode contact to be formed later (e.g., the electrodes 16a and 16b). In some embodiments, the second passivation layer 142 covers the edges of the first passivation layer 141. In some embodiments, the second passivation layer 142 covers the entire top surface and sidewalls of the first passivation layer 141. The second passivation layer 142 may encapsulate the first passivation layer 141.

In some embodiments, the second passivation layer 142 has multiple openings corresponding to the multiple openings in the first passivation layer 141. For example, the second passivation layer 142 has an opening O421 and an opening O422 in the first region R1. The opening O421 corresponds to the opening O411 and the opening O422 corresponds to the opening O412. The width of the opening O421 is smaller than the width of the opening O411, and the opening O421 exposes a portion of the rectifier structure 15 located in the opening O411. The width of the opening O422 is smaller than the width of the opening O412, and the opening O422 exposes a portion of the substrate and epitaxial layer 10 located in the opening O412. For another example, the second passivation layer 142 has an opening O423 and an opening O424 in the second region R2, where the opening O423 corresponds to the opening O413 and the opening O424 corresponds to the opening O414. The width of the opening O423 is smaller than the width of the opening O413, and the opening O423 exposes a portion of the rectifier structure 15 located in the opening O413. The width of the opening O424 is smaller than the width of the opening O414, and the opening O424 exposes a portion of the substrate and epitaxial layer 10 located in the opening O414.

For the positions and configurations of the openings O411, O412, O413, O414, and the openings O421, O422, O423, and O424, reference may be made to the top view shown in FIG. 2. The configurations of the openings O411, O412, O413, O414, and the openings O421, O422, O423, and O424 may correspond to each other or not. For example, the opening O411 and opening O421 have corresponding shapes, and the opening O422 is located within the opening O412 and does not have a shape corresponding to the opening O412. In some embodiments, as shown in FIG. 2, the second passivation layer 142 has a plurality of openings O422 corresponding to the number of the vertical portions 164 of the cathode. In some embodiments, the plurality of openings O422 are separated from each other, all of which are located within openings O412, and the width of a single opening O422 is smaller than the width of the opening O412. The width of each of the plurality of openings O422 is smaller than that of the opening O412.

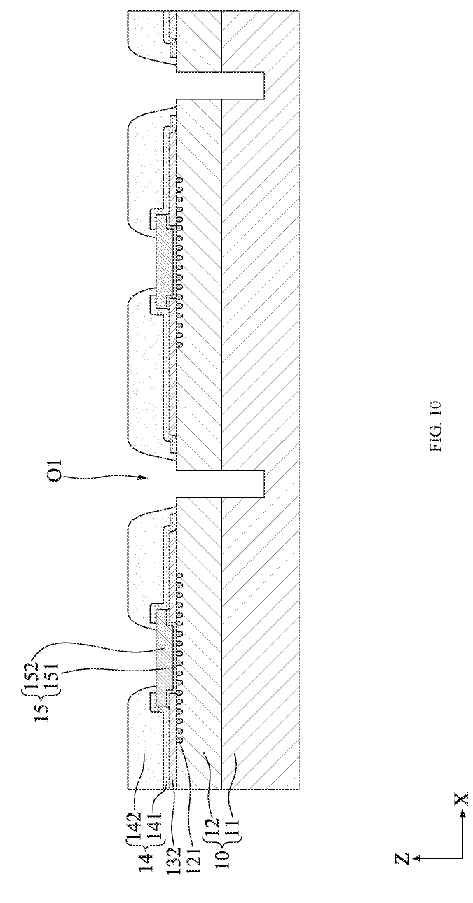

Referring to FIG. 10, the manufacturing method of the semiconductor device 2 includes etching the substrate and epitaxial layer 10 to form openings O1. In some embodiments, a patterned photoresist layer is formed on the structure shown in FIG. 9, exposing the substrate and epitaxial layer 10 in the openings O422 and O424. The exposed substrate and epitaxial layer 10 is then etched to form the openings O1. Each opening O1 extends from the top surface 12A of the substrate and epitaxial layer 10 into the substrate 11, without reaching the bottom surface 11B of the substrate and epitaxial layer 10. That is, the opening O1 does not extend through the substrate and epitaxial layer 10 in the thickness of the substrate and epitaxial layer 10 (the Z-direction). In some embodiments, a protective layer (e.g., a dielectric layer) may be formed on the structure shown in FIG. 9, exposing the substrate and epitaxial layer 10 in the openings O422 and O424. The exposed substrate and epitaxial layer 10 may then be etched to form the openings O1. In some embodiments, the etching step is performed for a predetermined length of time to control the openings O1 to stop in the substrate 11 and prevent the openings O1 from penetrating the substrate and epitaxial layer 10. In some embodiments, the width of the openings O1 is less than the minimum width of the opening O422 or O424. In some embodiments, the shape of the openings O1 corresponds to the shape of the opening O422 or O424, and the configuration of the openings O1 defines the configuration of the vertical portion 164 of the cathode to be formed later (the configuration of the openings O1 can be corresponded to the vertical portion 164 in FIG. 2). In some embodiments, the patterned photoresist layer or protective layer is removed after the etching step.

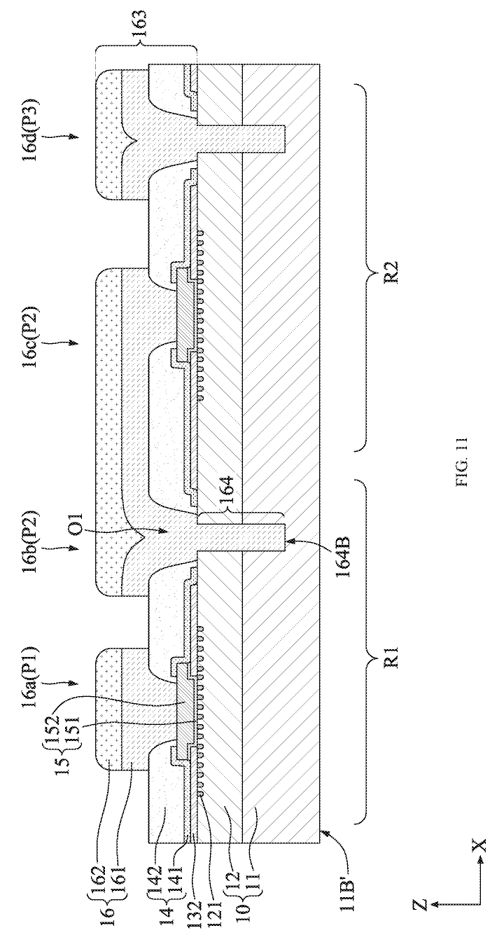

Referring to FIG. 11, the manufacturing method of the semiconductor device 2 includes forming the first conductive material layer 161 to fill multiple openings (e.g., the openings O421, O422, O423, and O424) in the second passivation layer 142 and the openings O1 in the substrate and epitaxial layer 10, and forming a second conductive material layer 162 to cover the first conductive material layer 161. The second conductive material layer 162 is formed on and in contact with the first conductive material layer 161. The method of forming the first conductive material layer 161 and the second conductive material layer 162 may include forming a seed layer on the top surface of the intermediate structure shown in FIG. 10; then forming a patterned photoresist layer (or a patterned dielectric layer) on a portion of the second passivation layer 142 to cover the area outside the cathode and anode; and then performing an electroplating process on the entire substrate and epitaxial layer 10. Because the area outside the cathode and anode is covered with the patterned photoresist layer (or a patterned dielectric layer), no metal layer is formed in the area outside the cathode and anode during electroplating. The electroplating process may include sequentially electroplating a first conductive material and a second conductive material to form the first conductive material layer 161 comprising the first conductive material and to form the second conductive material layer 162 comprising the second conductive material.

Thus, a portion of the second passivation layer 142 may be considered to be between the first electrode 16a (e.g., the first conductive material layer 161) and the rectifier structure 15. The opening O421 exposes a portion of the rectifier structure 15 (e.g., the second metal layer 152) such that the first conductive material layer 161 may be in contacted with and electrically connected to the rectifier structure 15.

In some embodiments, the first conductive material layer 161 comprises copper, and the second conductive material layer 162 comprises tin. In the embodiments of the present disclosure, the semiconductor device 2 does not contain lead. In some embodiments, after the electroplating process, the patterned photoresist layer (or patterned dielectric layer) is removed. In some embodiments, after removing the patterned photoresist layer (or patterned dielectric layer), the exposed seed layer is removed (e.g., using wet etching). The first conductive material layer 161 is filled into the openings O1. The portion of the first conductive material layer 161 filled into the openings O1 serves as the cathode’s vertical portion 164 for electrical connection to the subsequently formed metal layer 17. The vertical portion 164 has a bottom surface 164B that is within the substrate 11. The portions of the first conductive material layer 161 and the second conductive material layer 162 located on the top surface 12A of the substrate and epitaxial layer 10 serve as the horizontal portions 163 of the anode and the cathode, providing electrical paths (or electrical contacts) for connection to an external voltage. The vertical portion 164 is connected to its corresponding horizontal portion 163 through the first conductive material layer 161.

As described above with respect to FIGS. 1 and 2, the first conductive material layer 161 and the second conductive material layer 162 together form the plurality of electrodes 16, defining the plurality of electrode pads P1, P2, and P3. The portion of the electrode pad P1 located in the first region R1 serves as the anode 16a. The electrode pad P2 covers a portion of the first region R1 and a portion of the second region R2, where the portion of the electrode pad P2 located in the first region R1 serves as the cathode 16b, and the portion of the electrode pad P2 located in the second region R2 serves as the anode 16c. The portion of the electrode pad P3 located in the second region R2 serves as the cathode 16d.

Specifically, as shown in FIGS. 1 and 2, the first conductive material layer 161 and the second conductive material layer 162 together form the plurality of electrodes 16, defining the plurality of electrode pads P1, P2, P3 and P4. The electrode pad P1 covers a portion of the first region R1 and a portion of the third region R3, where the portion of the electrode pad P1 located in the first region R1 serves as the anode 16a, and the portion of the electrode pad P1 located in the third region R3 serves as the anode 16e. The electrode pad P2 covers a portion of the first region R1 and a portion of the second region R2, where the portion of the electrode pad P2 located in the first region R1 serves as the cathode 16b, and the portion of the electrode pad P2 located in the second region R2 serves as the anode 16c.

The electrode pad P3 covers a portion of the second region R2 and a portion of the fourth region R4, where the portion of the electrode pad P3 located in the second region R2 serves as the cathode 16d, and the portion of the electrode pad P3 located in the fourth region R4 serves as the cathode 16h. The electrode pad P4 covers a portion of the third region R3 and a portion of the fourth region R4, where the portion of the electrode pad P4 located in the third region R3 serves as the cathode 16f, and the portion of the electrode pad P4 located in the fourth region R4 serves as the anode 16g. Although the electrode pad P4 is not shown in FIG. 11, the top view of the semiconductor device 2 is similar to that of FIG. 2, and its description is not repeated here.

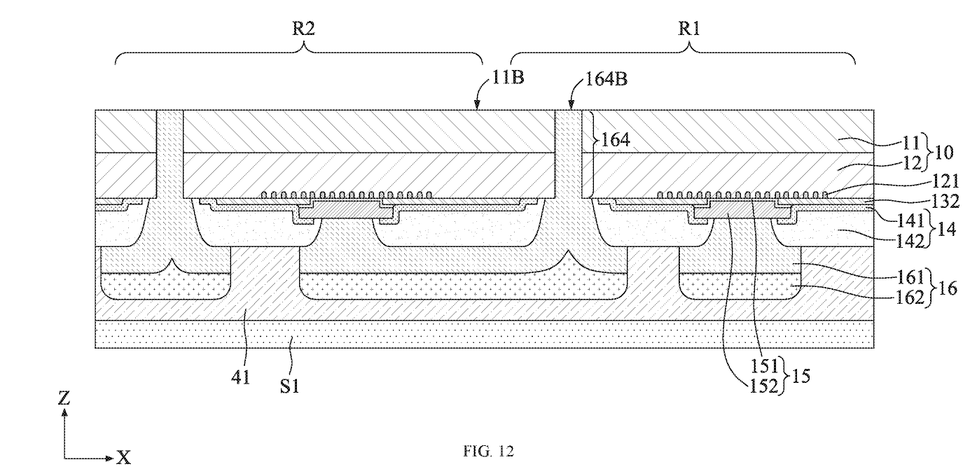

Referring to FIG. 12, the manufacturing method of the semiconductor device 2 includes thinning the substrate and epitaxial layer 10 to expose the bottom 164B of the vertical portion 164 in the substrate and epitaxial layer 10. In some embodiments, to remove a portion of the substrate 11 from the bottom surface 11B' of the substrate and epitaxial layer 10, the intermediate structure shown in FIG. 11 is flipped over and then bonded to a carrier S1 via a bonding layer 41 (e.g., a molding material or an encapsulation material). In some embodiments, backside grinding and/or chemical mechanical polishing (CMP) is performed on the bottom surface 11B' of the substrate and epitaxial layer 10 shown in FIG. 11 until the bottom 164B of the vertical portion 164 is exposed. In some embodiments, the thinned substrate and epitaxial layer 10 has a thickness ranging from 100 to 200 micrometers (μm). After the thinning step, the bottom 164B of the vertical portion 164 is exposed, with a bottom surface 11B of the substrate and epitaxial layer 10 that is approximately flush with the bottom 164B of the vertical portion 164.

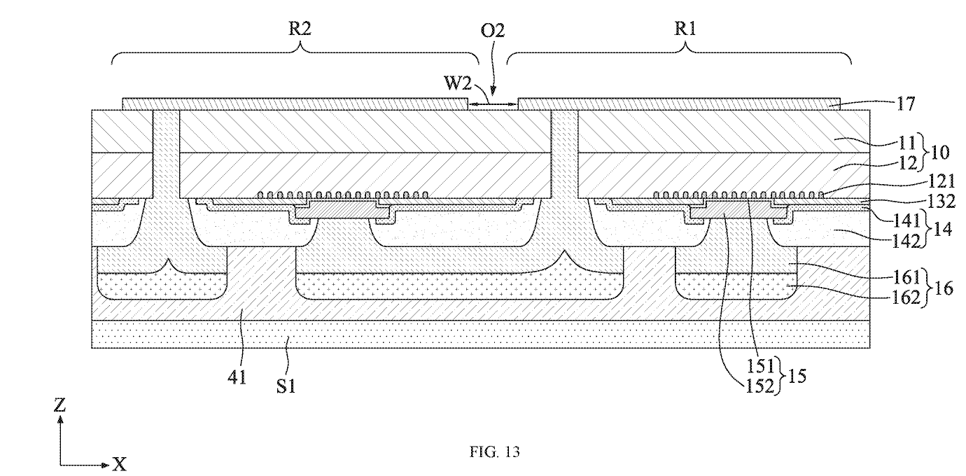

Referring to FIG. 13, the manufacturing method of the semiconductor device 2 includes forming the metal layer 17 on the bottom surface 11B of the substrate and epitaxial layer 10, where the metal layer 17 has an opening O2 to define the location of the isolation structure 18 to be formed later. In some embodiments, forming the metal layer 17 includes: forming a metal material layer by sputtering on the bottom surface 11B of the substrate and epitaxial layer 10; forming a patterned photoresist layer on the metal material layer; etching the metal material layer using the patterned photoresist layer as a mask to form the metal layer 17 having the opening O2; and removing the patterned photoresist layer. In some embodiments, after forming the metal layer 17, a thermal annealing process (e.g., laser annealing) is performed on the metal layer 17 to form a low-resistance ohmic contact at the interface between the metal layer 17 and the substrate and epitaxial layer 10. Because the vertical portions 164 of the cathodes (e.g., the electrodes 16b and 16d) are exposed from the bottom surface 11B of the substrate and epitaxial layer 10, the metal layer 17 contacts the bottom surfaces 164B of the vertical portions 164 to be electrically connected to the cathodes. The opening O2 in the metal layer 17 defines the location of the isolation structure 18 to be formed later. Therefore, it can be understood that, from a top view of the semiconductor device 2, the opening O2 surrounds each region (e.g., R1 and R2) of the substrate and epitaxial layer 10. In some embodiments, the opening O2 has a width W2. In some embodiments, the vertical projection of the opening O2 is located in the termination region R12 and is separated from the doped regions 121.

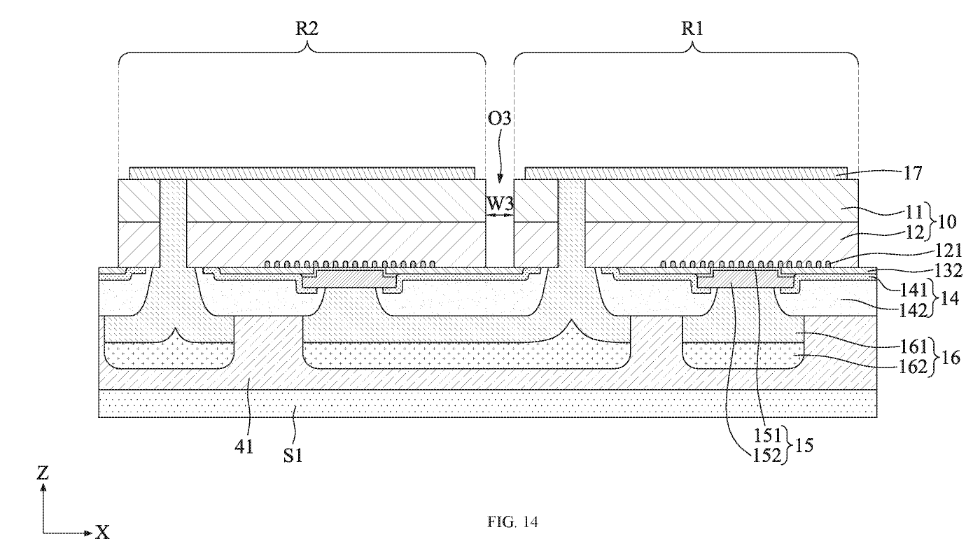

Referring to FIG. 14, the manufacturing method of the semiconductor device 2 includes etching the substrate and epitaxial layer 10 exposed from the metal layer 17 by the opening O2 to form an opening O3 that penetrates the substrate and epitaxial layer 10. The opening O3 extends from the bottom surface 11B of the substrate and epitaxial layer 10 toward the top surface 12B of the substrate and epitaxial layer 10 and through the thickness of the substrate and epitaxial layer 10. In some embodiments, forming the opening O3 includes forming a patterned photoresist layer on the metal layer 17, where the patterned photoresist layer has an opening corresponding to and overlapping with the opening O3; etching the substrate and epitaxial layer 10 (e.g., wet etching or dry etching) using the patterned photoresist layer as a mask; and removing the patterned photoresist layer. In some embodiments, the patterned photoresist layer defining the metal layer 17 in the step of FIG. 13 and the patterned photoresist layer defining the opening O3 in the substrate and epitaxial layer 10 in the step of FIG. 14 may be formed using the same photomask, and thus the patterned photoresist layers in both steps can have the same pattern. In some embodiments, a wet etching process may be used to form the opening O2 in the metal layer 17. The wet etching process causes the metal layer 17 to recede, and therefore even using the same photomask, the width W2 of the opening O2 is substantially greater than the width W3 of the opening O3. In other embodiments, the patterned photoresist layers in the step of FIG. 13 and the step of FIG. 14 are formed using different photomasks, however, the patterned photoresist layer in the step of FIG. 14 has a pattern corresponding to the patterned photoresist layer in the step of FIG. 13 with a smaller opening width. Therefore, the width W2 of the opening O2 is greater than the width W3 of the opening O3. In some embodiments, the dielectric layer 132 may serve as an etch stop layer, and so the etching process for removing portions of the substrate and epitaxial layer 10 stops at the dielectric layer 132.

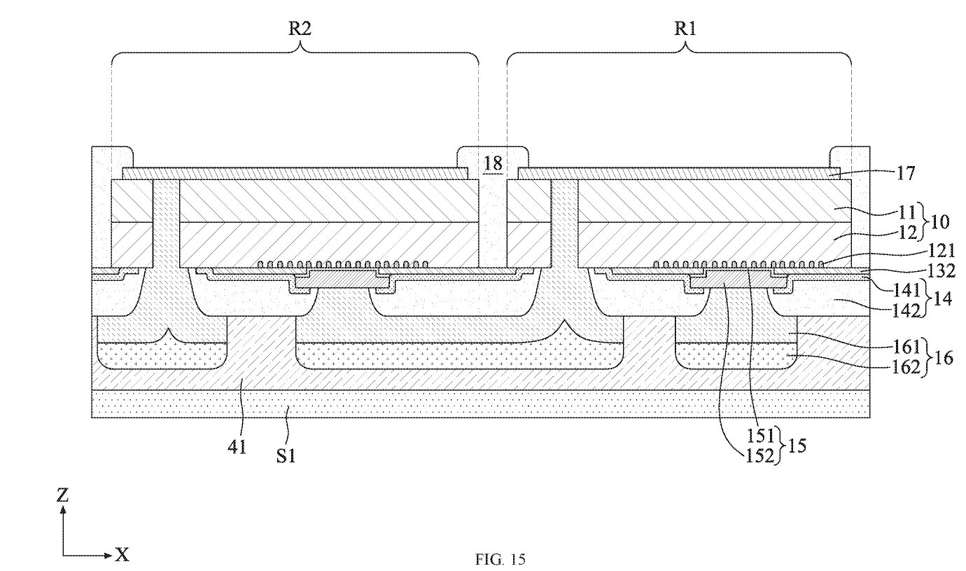

Referring to FIG. 15, the manufacturing method of the semiconductor device 2 includes filling the openings O2 and O3 with polyimide to form the isolation structure 18. Reference may be made to FIG. 2 for the top view of the isolation structure 18. In the top view of FIG. 2, the isolation structure 18 surrounds each region (e.g., R1, R2, R3, and R4) of the substrate and epitaxial layer 10, defining the plurality of dies C1, C2, C3, and C4. That is, the isolation structure 18 includes portions respectively separating R1 and R2, R1 and R3, R3 and R4, and R2 and R4.

Returning back to FIG. 15, forming the isolation structure 18 may include: coating polyimide on the bottom surface 11B of the substrate and epitaxial layer 10, where the polyimide fills the opening O3 in the substrate and epitaxial layer 10 and the opening O2 in the metal layer 17, and covers the metal layer 17; and performing a photolithography process on the polyimide (including steps such as exposure, development, and curing) to form the isolation structure 18 as shown in FIG. 15. Because the openings O2 and O3 have different widths, a portion of the isolation structure 18 above the bottom surface 11B of the substrate and epitaxial layer 10 and a portion located within the substrate and epitaxial layer 10 have different widths, with the portion of the isolation structure 18 above the bottom surface 11B of the substrate and epitaxial layer 10 having a larger width.

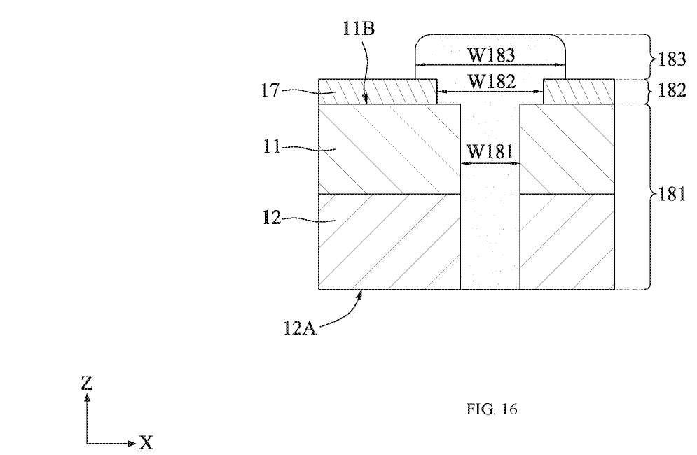

For illustrative purposes, FIG. 16 is an enlarged view of the isolation structure 18 made based on the cross-sectional structure of FIG. 15. Referring to FIG. 16, the isolation structure 18 includes a first portion 181 located within the substrate and epitaxial layer 10, a second portion 182 located on the bottom surface 11B of the substrate and epitaxial layer 10 and surrounded by the metal layer 17, and a third portion 183 located on the surface of the metal layer 17 away from the substrate and epitaxial layer 10.

The first portion 181 has a width W181, the second portion 182 has a width W182, and the third portion 183 has a width W183. In some embodiments, the width W181 of the first portion 181 is smaller than the width W183 of the third portion 183. In some embodiments, the width W181 of the first portion 181 is smaller than the width W182 of the second portion 182. In some embodiments, the width W182 of the second portion 182 is smaller than the width W183 of the third portion 183. To ensure that the polyimide completely fills the opening O2 in the metal layer 17, the polyimide may be disposed to cover the entire metal layer 17, and a subsequent photolithography process may leave a portion of the polyimide on the metal layer 17 with a width greater than the width W2 of the opening O2, but the present disclosure is not limited thereto. In some embodiments, the width W183 of the third portion 183 is approximately the same as the width W182 of the second portion 182.

In other words, the first portion 181 extends through the substrate and epitaxial layer 10 (the substrate 11 and the epitaxial layer 12), and is between the bottom surface 11B and the top surface 12A of the substrate and epitaxial layer 10. The first portion 181 includes polyimide completely filled in the opening O3. The second portion 182 extends from the bottom surface 11B away from the substrate and epitaxial layer 10 and includes polyimide completely filled in the opening O2. The second portion 182 covers the first portion 181 and a portion of the bottom surface 11B of the substrate and epitaxial layer 10 exposed by the opening O2. The second portion 182 may have a thickness the same as that of the metal layer 17. The third portion 183 extends from the surface of the metal layer 17 not in contact with the substrate and epitaxial layer 10 (referred to as the bottom surface of the metal layer 17, which is away from the substrate and epitaxial layer 10) away from the metal layer with a certain thickness. The third portion 183 covers the first portion 181, the second portion 182, and a portion of the metal layer 17 surrounding the second portion 182. Thus, the isolation structure 18 includes the second portion 182 and the third portion 183 that protrude from the top surface 12A of the substrate and epitaxial layer 10 (i.e., outside of the substrate and epitaxial layer 10), and have widths greater than the first portion 181 that is inside the substrate and epitaxial layer 10.

Generally speaking, products with a higher voltages require greater electrical isolation, which in turn increases the size of the electrical isolation components, leading to an increase in product size. The isolation structure 18 of embodiments of the present disclosure comprises polyimide, thus exhibiting excellent electrical isolation properties. Even when applied to a silicon carbide substrate, it still provides good electrical isolation, making it suitable for high-voltage products (e.g., high-voltage components ranging from 650 to 1200 volts or even up to 1500 volts). Furthermore, the isolation structure 18 of embodiments of the present disclosure has a greater width outside the substrate and epitaxial layer 10, forming a configuration similar to a round iron nail or a thumbtack. This effectively prevents adhesion issues caused by stress differences between the dissimilar dielectric materials of polyimide and silicon carbide, thereby achieving excellent product durability.

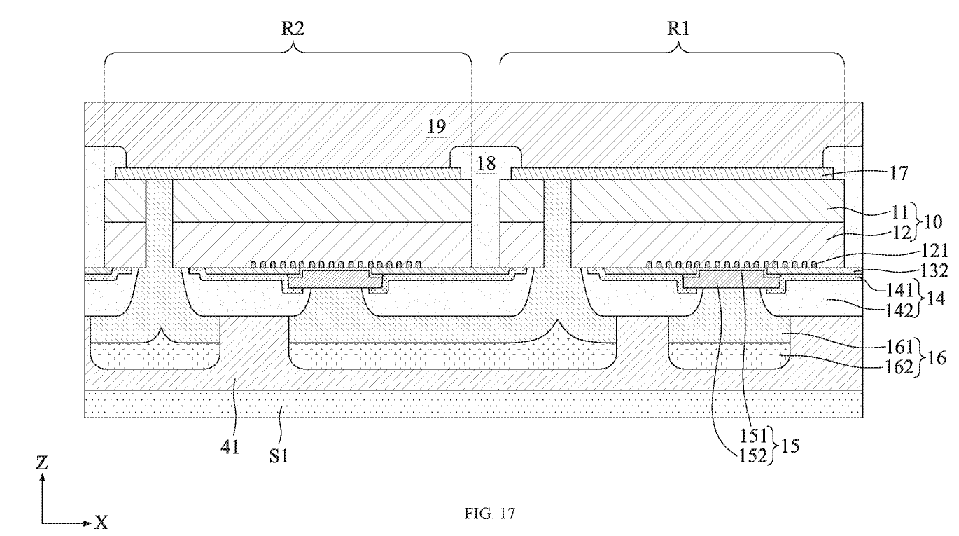

Referring to FIG. 17, the manufacturing method of the semiconductor device 2 includes forming the molding material layer 19 over the bottom surface 11B of the substrate and epitaxial layer 10, where the molding material layer 19 covers the metal layer 17 and the isolation structure 18. The molding material layer 19 protects the metal layer 17 from moisture and oxidation. Furthermore, since the thickness of the substrate and epitaxial layer 10 is very small, which may result in an unstable structure of the semiconductor device 2, the molding material layer 19 helps provide sufficient support for the semiconductor device 2, which improves the durability of the semiconductor device 2. In some embodiments, a coating process or a deposition process is performed over the bottom surface 11B of the substrate and epitaxial layer to form the molding material layer 19.

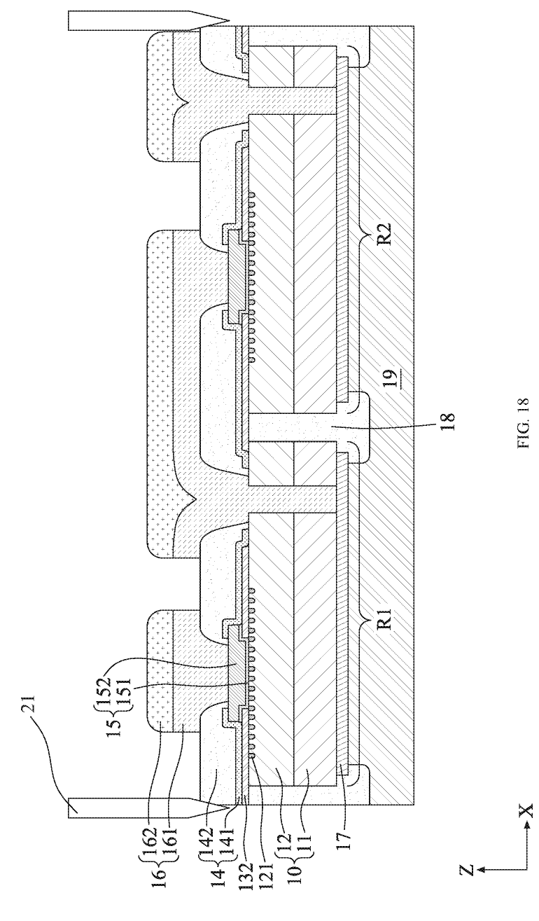

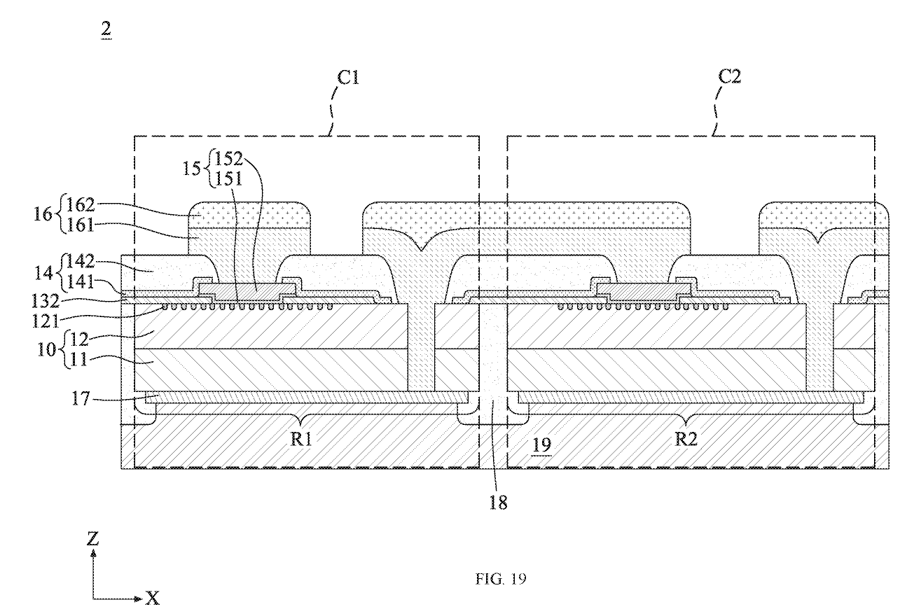

Referring to FIGS. 18-19, the manufacturing method of the semiconductor device 2 includes peeling the intermediate structure of FIG. 17 from the carrier S1 and cutting the substrate and epitaxial layer 10 from above its top surface 12A to form the semiconductor device 2 as shown in FIG. 19. Basically, the carrier S1 and the bonding layer 41 are removed, which may be implemented by various applicable methods. In some embodiments, the bonding layer 41 is a dicing tape, and may be removed by peeling off. In some embodiments, the intermediate structure of FIG. 17 is flipped before the peeling step. In some embodiments, the carrier S1 and the bonding layer 41 are removed from the structure shown in FIG. 17, and the resulting structure is then flipped over so that the top surface 12A of the substrate and epitaxial layer 10 faces upward, as shown in FIG. 18. The structure of FIG. 18 may be diced by a cutter 21 along the scribe lines to obtain the semiconductor device 2 as shown in FIG. 19. The semiconductor device 2 has a structure similar to the semiconductor device 1, and therefore a top view of the semiconductor device 2 can be seen with reference to FIG. 2. The semiconductor device 2 may be a bridge rectifier device comprised of the first die C1, the second die C2, the third die C3, and the fourth die C4.=

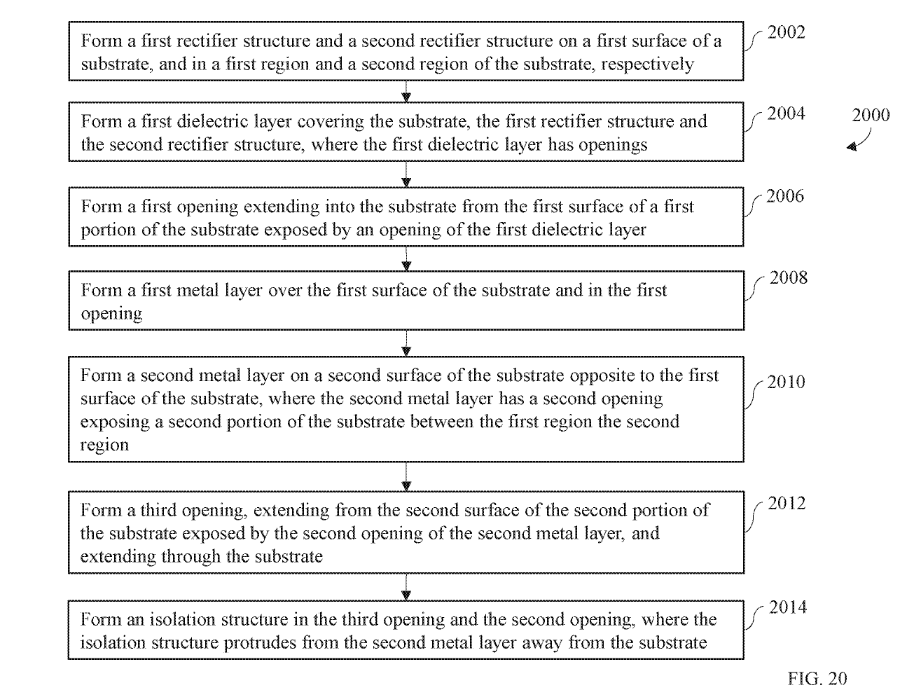

FIG. 20 is a flowchart of a method 2000 of manufacturing a semiconductor device according to embodiments of the present disclosure. The method 2000 may be representative of operations for manufacturing the semiconductor device 1 or 2 as described above. As shown, at step 2002, a first rectifier structure and a second rectifier structure are formed on a first surface of a substrate, and in a first region and a second region of the substrate, respectively. The first region may be adjacent to the second region.

At step 2004, a first dielectric layer is formed covering the substrate, the first rectifier structure and the second rectifier structure, where the first dielectric layer has openings, which respectively exposes a portion of the first rectifier structure, a portion of the second rectifier structure, and a first portion of the substrate between the first rectifier structure and the second rectifier structure.

At step 2006, a first opening is formed extending into the substrate from the first surface of the first portion of the substrate exposed by the first dielectric layer. At step 2008, a first metal layer is formed over the first surface of the substrate and in the first opening.

At step 2010, a second metal layer is formed on a second surface of the substrate opposite to the first surface of the substrate, where the second metal layer has a second opening exposing a second portion of the substrate between the first region the second region.

At step 2012, a third opening is formed extending from the second surface of the second portion of the substrate exposed by the second opening of the second metal layer, and extending through the substrate.

At step 2014, an isolation structure is formed in the third opening and the second opening, where the isolation structure protrudes from the second metal layer away from the substrate.

Further embodiments are provided in the following.

In an embodiment, a semiconductor device is provided that includes: a plurality of semiconductor dies, each of the plurality of semiconductor dies comprising a substrate and epitaxial layer, a rectifier structure disposed on a top surface of the substrate and epitaxial layer, a first electrode disposed on the rectifier structure, and a second electrode extending from above the top surface toward a bottom surface of the substrate and epitaxial layer; and an isolation structure of the substrate and epitaxial layer, configured to isolate adjacent semiconductor dies of the plurality of semiconductor dies, a material of the isolation structure including polyimide, wherein the isolation structure extends from the top surface of the substrate and epitaxial layer toward the bottom surface and protrudes from the bottom surface.

Optionally, in the preceding embodiment, each of the plurality of semiconductor dies further comprises a first dielectric layer located between the rectifier structure and the first electrode, and a material of the first dielectric layer comprises polyimide.

Optionally, in any of the preceding applicable embodiments, the first dielectric layer has an opening exposing a portion of the rectifier structure such that the first electrode is electrically connected to the rectifier structure.

Optionally, in any of the preceding applicable embodiments, each of the plurality of semiconductor dies further comprises a second dielectric layer located between the rectifier structure and the first dielectric layer, and a material of the first dielectric layer comprises silicon nitride, silicon oxide, or a combination thereof.

Optionally, in any of the preceding applicable embodiments, the semiconductor device further comprises: a molding material layer covering the bottom surface of the substrate and epitaxial layer and the isolation structure protruding from the bottom surface of the substrate.

Optionally, in any of the preceding applicable embodiments, the first electrode is an anode, the second electrode is a cathode, and the plurality of semiconductor dies include a first die, a second die, a third die, and a fourth die, the anode of the first die and the anode electrode of the third die are electrically connected, the cathode of the first die and the anode of the second die are electrically connected, the anode of the second die and the cathode of the fourth die, and the cathode of the third die and the anode of the fourth die are electrically connected.

In another embodiment, a semiconductor device is provided that includes : a substrate having a first surface and a second surface opposite to each other; an isolation structure extending from the first surface toward the second surface of the substrate and penetrating the substrate, wherein the isolation structure protrudes from the second surface and at least divides the substrate into a first region and a second region adjacent to each other in a horizontal direction; a first rectifier structure located on the first surface of the first region of the substrate; a second rectifier structure located on the first surface of the second region of the substrate; a first metal layer located on the second surface of the substrate; and a second metal layer located on the first surface of the substrate, the second metal layer comprising: a first electrode pad, located on the first rectifier structure and electrically connected to the first rectifier structure; and a second electrode pad, comprising a first portion extending on the first surface of the substrate and a second portion extending from the first surface toward the second surface, wherein the first portion covers part of the first region and part of the second region and is electrically connected to the second rectifier structure, and the second portion passes through the substrate and is electrically connected to the first metal layer.

Optionally, in the preceding embodiment, the isolation structure penetrates the first metal layer to electrically isolate a portion of the first metal layer located in the first region from a portion of the first metal layer located in the second region.

Optionally, in any of the preceding applicable embodiments, a width of a portion of the isolation structure located in the substrate is smaller than a width of a portion of the isolation structure located in the first metal layer.

Optionally, in any of the preceding applicable embodiments, the width of the portion of the isolation structure located in the first metal layer is smaller than a width of a portion of the isolation structure protruding from the first metal layer.

Optionally, in any of the preceding applicable embodiments, a first portion of the isolation structure located in the substrate has a first width, a second portion of the isolation structure protruding from the second surface of the substrate has a second width, and the first width is smaller than the second width.

Optionally, in any of the preceding applicable embodiments, a material of the isolation structure comprises polyimide.

Optionally, in any of the preceding applicable embodiments, a material of the substrate comprises silicon carbide, and a thickness of the substrate is between 100 and 200 microns.

Optionally, in any of the preceding applicable embodiments, a second portion of the second electrode pad has a bottom surface that is approximately flush with the second surface of the substrate.

Optionally, in any of the preceding applicable embodiments, the semiconductor device further includes: a first dielectric layer located on the first surface of the substrate and covering the first rectifier structure and the second rectifier structure, wherein the first dielectric layer has a first opening exposing a portion of the first rectifier structure and a second opening exposing a portion of the second rectifier structure; and a second dielectric layer located between the first dielectric layer and the second metal layer.

Optionally, in any of the preceding applicable embodiments, a material of the first dielectric layer comprises nitride or oxide, and a material of the second dielectric layer comprises polyimide.

Optionally, in any of the preceding applicable embodiments, the second dielectric layer surrounds the second portion of the second electrode pad viewed from a top perspective.

In yet another embodiment, a manufacturing method of a semiconductor device is provided that includes: forming a first rectifier structure and a second rectifier structure on a first surface of a substrate, wherein the substrate is defined with a first region and a second region adjacent to the first region, and the first rectifier structure and the second rectifier structure are respectively located in the first region and the second region of the substrate; forming a first dielectric layer to cover the substrate, the first rectifier structure and the second rectifier structure, wherein the first dielectric layer has a plurality of openings, respectively exposing a portion of the first rectifier structure, a portion of the second rectifier structure, and a portion of the substrate located between the first rectifier structure and the second rectifier structure; removing the portion of the substrate exposed by the first dielectric layer to form a first opening; forming a first metal layer on the first surface of the substrate and in the first opening; forming a second metal layer on a second surface of the substrate opposite to the first surface, wherein the second metal layer has a second opening exposing the substrate between the first region the second region; removing a portion of the substrate exposed by the second opening of the second metal layer to form a third opening in the substrate; and forming an isolation structure in the third opening and the second opening, wherein the isolation structure protrudes from the second metal layer.

Optionally, in the preceding embodiment, the manufacturing method further includes: forming a molding material layer to cover the second metal layer and the isolation structure.

Optionally, in any of the preceding applicable embodiments, the manufacturing method further includes: before forming the first rectifier structure and the second rectifier structure, forming an etch stop layer on the first surface of the substrate; and wherein the third opening of the substrate stops at the etch stop layer.

Optionally, in any of the preceding applicable embodiments, the manufacturing method further includes: before forming the second metal layer, reducing a thickness of the substrate to expose a bottom of the first metal layer in the substrate.

Optionally, in any of the preceding applicable embodiments, the bottom of the first metal layer is approximately flush with the second surface of the substrate.

Optionally, in any of the preceding applicable embodiments, the second metal layer covers the bottom of the first metal layer.

Optionally, in any of the preceding applicable embodiments, a top surface of the isolation structure is approximately flush with the first surface of the substrate.

Optionally, in any of the preceding applicable embodiments, a material of the first dielectric layer comprises polyimide, and the manufacturing method further comprises: before forming the first dielectric layer, forming the second dielectric layer to cover the substrate, the first rectifier structure and the second rectifier structure, wherein the second dielectric layer has a plurality of openings overlapping with the plurality of openings of the first dielectric layer.

Optionally, in any of the preceding applicable embodiments, a material of the second dielectric layer comprises nitride, oxide, or a combination thereof.

Optionally, in any of the preceding applicable embodiments, the manufacturing method further includes: forming epitaxially an epitaxial layer on the substrate to form the substrate, wherein a doping concentration of the substrate is greater than a doping concentration of the epitaxial layer.

Optionally, in any of the preceding applicable embodiments, forming the first metal layer comprises: forming a copper-containing metal layer on the first surface of the substrate and in the first opening by electroplating; and forming a tin-containing metal layer on the copper-containing metal layer by electroplating.

In this disclosure, for description convenience, spatially relative terms such as "below", "under", "lower", "above", "upper", "left side", "right side", and so on, may be used to describe the relationship of one component or feature with another one or more components or features, as shown in the accompanying drawings. The spatially relative terms are not only used to depict the orientations in the accompanying drawings, but also intended to encompass different orientations of a device in use or operation. A device may be oriented in other ways (rotated 90 degrees or in other orientations), and the spatially relative terms used herein may be interpreted in a corresponding way similarly. It should be understood that when a component is referred to as being "connected" or "coupled" to another component, it can be directly connected or coupled to another component or an intervening component may be present.

As used herein, the terms "approximately", "basically", "substantially" and "about" are used to describe and account for small variations. When used in conjunction with an event or instance, the terms may refer to an embodiment of exact occurrence of an event or instance as well as an embodiment where the event or instance is close to occurrence. As used herein with respect to a given value or range, the term "about" generally means being within ±10%, ±5%, ±1%, or ±0.5% of the given value or range. A range herein may be referred to as being from one endpoint to the other or as being between two endpoints. All ranges disclosed herein are inclusive of the endpoints unless otherwise indicated. The term "substantially coplanar" may mean that the difference of positions of two surfaces with reference to the same plane is within a few micrometers (μm), e.g., the difference is within 10 μm, within 5 μm, within 1 μm, or within 0.5 μm. When values or characteristics are referred to as being "substantially" the same, the term may refer to a value that is within ±10%, ±5%, ±1%, or ±0.5% of the mean of the values.

The foregoing has outlined features of some embodiments and detailed aspects of present disclosure. The embodiments described in the present disclosure may be readily used as a basis for designing or modifying other processes and structures in order to carry out the same or similar purposes and/or to achieve the same or similar advantages of the embodiments presented herein. Such equivalent constructions do not depart from the spirit and scope of the present disclosure, and various changes, substitutions, and alterations can be made without departing from the spirit and scope of the present disclosure.

Although the description has been described in detail, it should be understood that various changes, substitutions and alterations can be made without departing from the spirit and scope of this disclosure as defined by the appended claims. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, which may perform substantially the same function or achieve substantially the same result as the corresponding embodiments described herein, may be utilized according to the present disclosure . Accordingly, the appended claims are intended to include within their scope such processes, machines, manufacture, compositions of matter, means, methods, or steps.

What is claimed:

1. A semiconductor device, comprising:
a plurality of semiconductor dies, each of the plurality of semiconductor dies comprising:
a portion of a substrate and epitaxial layer,
a rectifier structure disposed on a top surface of the substrate and epitaxial layer,
a first electrode disposed on the rectifier structure, and
a second electrode extending from a bottom surface of the substrate and epitaxial layer toward and above the top surface of the substrate and epitaxial layer; and
an isolation structure of the substrate and epitaxial layer, configured to isolate the plurality of semiconductor dies, wherein the isolation structure comprises polyimide, and extends from the top surface of the substrate and epitaxial layer toward the bottom surface of the substrate and epitaxial layer and protrudes from the bottom surface of the substrate and epitaxial layer.

2. The semiconductor device of claim 1, wherein each of the plurality of semiconductor dies further comprises a first dielectric layer of polyimide covering the top surface of the substrate and epitaxial layer, and partially covering the rectifier structure.

3. The semiconductor device of claim 2, wherein the first dielectric layer has an opening exposing a portion of the rectifier structure such that the first electrode is electrically connected to the rectifier structure.

4. The semiconductor device of claim 2, wherein each of the plurality of semiconductor dies further comprises a second dielectric layer between the rectifier structure and the first dielectric layer, and the second dielectric layer comprises silicon nitride, silicon oxide, or a combination thereof.

5. The semiconductor device of claim 1, further comprising:
a molding material layer covering the bottom surface of the substrate and epitaxial layer, wherein the isolation structure protrudes from the bottom surface of the substrate and epitaxial layer.

6. The semiconductor device of claim 1, wherein,
the first electrode is an anode, the second electrode is a cathode, and the plurality of semiconductor dies include a first die, a second die, a third die, and a fourth die;
the anode of the first die and the anode of the third die are electrically connected, the cathode of the first die and the anode of the second die are electrically connected, the cathode of the second die and the cathode of the fourth die are electrically connected, and the cathode of the third die and the anode of the fourth die are electrically connected.

7. A semiconductor device, comprising:
a substrate having a first surface and a second surface opposite to each other;
an isolation structure extending from the first surface of the substrate toward the second surface of the substrate and protruding from the second surface of the substrate, the isolation structure dividing the substrate at least into a first region and a second region adjacent to each other;
a first rectifier structure on the first surface of the substrate in the first region;
a second rectifier structure on the first surface of the substrate in the second region;
a first metal layer on the second surface of the substrate; and
a second metal layer comprising:
a first electrode pad on the first rectifier structure and electrically connected to the first rectifier structure; and
a second electrode pad, comprising a first portion extending on the first surface of the substrate and a second portion extending from the first surface of the substrate toward the second surface of the substrate, wherein the first portion covers a portion of the first region and a portion of the second region and is electrically connected to the second rectifier structure, and the second portion extends through the substrate and is electrically connected to the first metal layer.

8. The semiconductor device of claim 7, wherein the isolation structure comprises a first portion that protrudes from the second surface of the substrate and extends through the first metal layer, the second portion electrically isolating a portion of the first metal layer located in the first region from a portion of the first metal layer located in the second region.

9. The semiconductor device of claim 8, wherein a width of a second portion of the isolation structure located in the substrate is smaller than a width of the first portion of the isolation structure.

10. The semiconductor device of claim 9, wherein the isolation structure further comprises a third portion that protrudes from a surface of the first metal layer away from the substrate, the width of the first portion of the isolation structure is smaller than a width of the third portion of the isolation structure.

11. The semiconductor device of claim 7, wherein a material of the isolation structure comprises polyimide.

12. The semiconductor device of claim 7, wherein the second portion of the second electrode pad has a bottom surface that is approximately flush with the second surface of the substrate.

13. The semiconductor device of claim 7, further comprising:
a first dielectric layer located on the first surface of the substrate and covering the first rectifier structure and the second rectifier structure, wherein the first dielectric layer has a first opening exposing a portion of the first rectifier structure and a second opening exposing a portion of the second rectifier structure; and
a second dielectric layer covering the first dielectric layer .

14. The semiconductor device of claim 13, wherein a material of the first dielectric layer comprises nitride or oxide, and a material of the second dielectric layer comprises polyimide.

15. The semiconductor device of claim 13, wherein the second dielectric layer surrounds the second portion of the second electrode pad in a top view of the semiconductor device.

16. A method comprising:
forming a first rectifier structure and a second rectifier structure on a first surface of a substrate, wherein the first rectifier structure and the second rectifier structure are respectively located in a first region and a second region of the substrate, the first region being adjacent to the second region;
forming a first dielectric layer covering the substrate, the first rectifier structure and the second rectifier structure, wherein the first dielectric layer has a plurality of openings, respectively exposing a portion of the first rectifier structure, a portion of the second rectifier structure, and a first portion of the substrate between the first rectifier structure and the second rectifier structure;
forming a first opening extending into the substrate from the first surface of the first portion of the substrate exposed by the first dielectric layer;
forming a first metal layer over the first surface of the substrate and in the first opening;
forming a second metal layer on a second surface of the substrate opposite to the first surface of the substrate, wherein the second metal layer has a second opening exposing a second portion of the substrate between the first region the second region;
forming a third opening, extending from the second surface of the second portion of the substrate exposed by the second opening of the second metal layer, and extending through the substrate; and
forming an isolation structure in the third opening and the second opening, wherein the isolation structure protrudes from the second metal layer away from the substrate.

17. The method of claim 16, further comprising:
forming a molding material layer over the second surface of the substrate covering the second metal layer and the isolation structure.

18. The method of claim 16, wherein forming the isolation structure comprises:
filing the third opening and the second opening with polyimide to form the isolation structure, wherein the third opening has a width smaller than the second opening.

19. The method of claim 18, wherein a portion the isolation structure protruding from the second metal layer away from the substrate has a width greater than the second opening.

20. The method of claim 16, further comprising:
before forming the second metal layer, reducing a thickness of the substrate such that a bottom of the first metal layer in the first opening is flush with the second surface of the substrate.
